(19) United States
(12) Patent Application Publication
(10) Pub. No.: US 2026/0082552 A1
(43) Pub. Date: Mar. 19, 2026

(54) MEMORY DEVICES AND METHODS OF MANUFACTURING THE SAME

(71) Applicant: Samsung Electronics Co., Ltd., Suwon-si (KR)

(72) Inventors: HOIN LEE, Suwon-si (KR); JIEUN LEE, Suwon-si (KR); SEIRYUNG CHOI, Suwon-si (KR)

(21) Appl. No.: 19/248,635

(22) Filed: Jun. 25, 2025

(30) Foreign Application Priority Data
Sep. 19, 2024 (KR) 10-2024-0126844

(51) Int. Cl. H10B 12/00

(52) U.S. Cl. CPC H10B 12/50; H10B 12/315; H10B 12/482; H10B 12/488

(57) ABSTRACT

Provided is a semiconductor device including a substrate that comprises an active cell region, a dummy cell region that extends around the active cell region in a plan view, and a peripheral circuit region that extends around the dummy cell region in a plan view; and a device isolation film in device isolation trenches in the active cell region and the dummy cell region, wherein the substrate further comprises: active patterns that are alternately arranged with the device isolation trenches in the active cell region; and dummy active patterns that are alternately arranged with the device isolation trenches in the dummy cell region, and at least one of the dummy active patterns has an upper surface that is closer than an upper surface of at least one of the active patterns to a lower surface of the substrate.

### CROSS-REFERENCE TO RELATED APPLICATIONS

This application is based on and claims priority under 35 U.S.C. § 119 to Korean Patent Application No. 10-2024-0126844, filed on Sep. 19, 2024, in the Korean Intellectual Property Office, the disclosure of which is incorporated by reference herein in its entirety.

### BACKGROUND OF THE INVENTION

The inventive concept relates to semiconductor devices and methods of manufacturing the same, and more particularly, to semiconductor devices having a cell region and a peripheral circuit region.

Due to the rapid development of the electronics industry and demands of users, electronic devices are becoming smaller and lighter. Therefore, high integration may be needed for semiconductor devices used in electronic devices, and design rules for components of semiconductor devices are being reduced, leading to microstructuring.

### SUMMARY OF THE INVENTION

The inventive concept may provide a semiconductor device with improved reliability.

In addition, the technical goals to be achieved by the inventive concept are not limited to the technical goals mentioned above, and other technical goals may be clearly understood by one of ordinary skill in the art from the following descriptions.

According to an aspect of the inventive concept, there is provided a semiconductor device including a substrate that comprises an active cell region, a dummy cell region that extends around the active cell region in a plan view, and a peripheral circuit region that extends around the dummy cell region in a plan view; and a device isolation film in device isolation trenches in the active cell region and the dummy cell region, wherein the substrate further comprises: active patterns that are alternately arranged with the device isolation trenches in the active cell region; and dummy active patterns that are alternately arranged with the device isolation trenches in the dummy cell region, and at least one of the dummy active patterns has an upper surface that is closer than an upper surface of at least one of the active patterns to a lower surface of the substrate.

According to an aspect of the inventive concept, there is provided a semiconductor device including a substrate that comprises an active cell region, a peripheral circuit region, and an interface region between the active cell region and the peripheral circuit region; an active pattern in the active cell region; a peripheral circuit active pattern in the peripheral circuit region; and an interface active pattern in the interface region, wherein the interface active pattern is between the active pattern and the peripheral circuit active pattern, and wherein an upper surface of the interface active pattern is closer than an upper surface of the active pattern to a lower surface of the substrate.

According to an aspect of the inventive concept, there is provided a semiconductor device including a substrate that comprises an active cell region, a peripheral circuit region, and an interface region between the active cell region and the peripheral circuit region; an active pattern in the active cell region; a peripheral circuit active pattern in the peripheral circuit region; and an interface active pattern in the interface region, wherein the interface active pattern is between the active pattern and the peripheral circuit active pattern, wherein an upper surface of the active pattern is at a first distance from a lower surface of the substrate, and wherein an upper surface of the interface active pattern is at a second distance from the lower surface of the substrate, and wherein the second distance is different from the first distance.

According to an aspect of the inventive concept, there is provided a method of manufacturing a semiconductor device, the method including preparing a substrate that comprises an active cell region comprising an active pattern, a dummy cell region comprising a first dummy active pattern and a second dummy active pattern, an interface region comprising a first interface active pattern and a second interface active pattern, and a peripheral circuit region comprising a peripheral circuit active pattern; etching at least a portion of the first interface active pattern; forming an interface insulation pattern in a space formed by the etching at least the portion of the first interface active pattern; and forming a plurality of word lines that overlaps the active pattern and the second dummy active pattern, on the interface insulation pattern.

In an embodiment, in the etching at least the portion of the first interface active pattern, the first interface active pattern overlaps the plurality of word lines in a vertical direction that is perpendicular to a lower surface of the substrate, and the second interface active pattern is free of an overlap with the plurality of word lines in the vertical direction.

In an embodiment, the etching at least the portion of the first interface active pattern comprises etching at least a portion of the first dummy active pattern.

In an embodiment, the first dummy active pattern faces the peripheral circuit region, and the second dummy active pattern is spaced apart from the peripheral circuit region with the first dummy active pattern therebetween.

### BRIEF DESCRIPTION OF THE DRAWINGS

Embodiments of the inventive concept will be more clearly understood from the following detailed description taken in conjunction with the accompanying diagrams in which:

FIG. 1 is a plan view illustrating a schematic configuration of a semiconductor device according to embodiments.

FIG. 2A is a plan view illustrating a schematic configuration of a semiconductor device according to embodiments.

FIG. 2B is a schematic plan view of an enlarged portion of FIG. 2A.

FIG. 3 is a plan view illustrating a schematic configuration of a semiconductor device according to embodiments.

FIG. 4A is a plan view illustrating a schematic configuration of a semiconductor device according to embodiments.

FIG. 4B is a schematic plan view of an enlarged portion of FIG. 4A.

FIGS. 5 to 8 are drawings illustrating a method of manufacturing a semiconductor device, according to embodiments.

FIGS. 9 to 12 are drawings illustrating a method of manufacturing a semiconductor device, according to embodiments.

FIGS. 13A, 13B, 13C, 13D, 14A, 14B, 14C, 14D, 15A, 15B, 15C, 15D, 16A, 16B, 16C, and 16D are drawings illustrating a method of manufacturing a semiconductor device, according to embodiments.

FIG. 17 is a cross-sectional view illustrating a semiconductor device and a method of manufacturing the same, according to embodiments.

FIG. 18 is a cross-sectional view illustrating a semiconductor device according to embodiments; and FIG. 19 is a cross-sectional view illustrating a semiconductor device according to embodiments.

### DETAILED DESCRIPTION OF THE INVENTION

In this specification, horizontal directions may include a first horizontal direction (e.g., X direction) and a second horizontal direction (e.g., Y direction) that intersect each other. A direction intersecting the first horizontal direction (e.g., X direction) and the second horizontal direction (e.g., Y direction) may be referred to as a vertical direction (e.g., Z direction). In this specification, a vertical level may be referred to as a height level in the vertical direction (e.g., Z direction) of any configuration. The term “level”, “vertical level”, “height” or the like may refer to a relative location with respect to a reference element in the vertical direction (e.g., Z direction). For example, a level, a vertical level, height, or the like may be a distance from the reference element (e.g., a substrate 12) in the vertical direction (e.g., Z direction). For example, a higher level may mean a farther distance from a lower surface of the substrate 12, and a lower level may mean a closer distance to the lower surface of the substrate 12 in the vertical direction (e.g., Z direction). The first horizontal direction and the second horizontal direction may be parallel with an upper surface and/or the lower surface of the substrate 12, and the vertical direction may be perpendicular to the upper surface and/or the lower surface of the substrate 12.

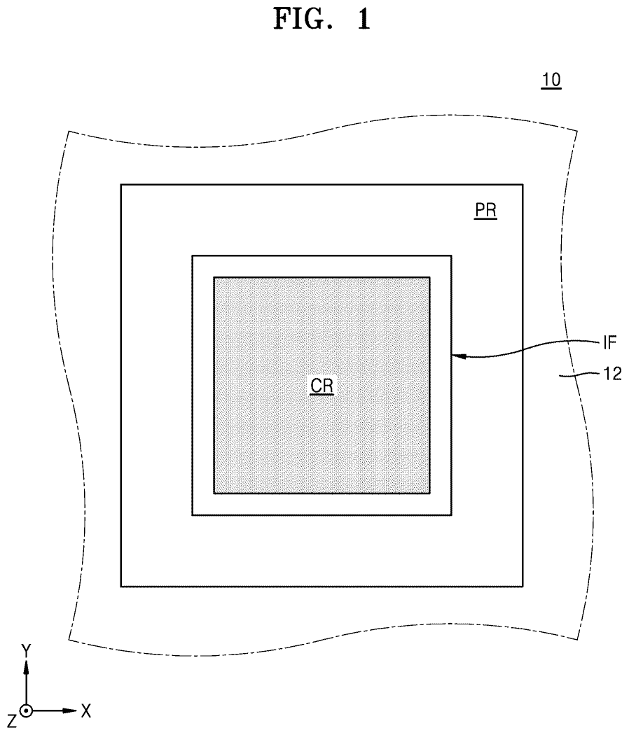

FIG. 1 is a plan view illustrating a schematic configuration of a semiconductor device 10 according to embodiments.

The semiconductor device 10 may include a substrate 12 including a cell region CR, a peripheral circuit region PR extending around (e.g., at least partially surrounding in a plan view) the cell region CR, and an interface region IF provided between the cell region CR and the peripheral circuit region PR.

The substrate 12 may include, for example, a semiconductor element, such as Si and Ge, and/or a compound semiconductor, such as SiGe, SiC, GaAs, InAs, and InP. The substrate 12 may include a conductive region, e.g., a well doped with an impurity or a structure doped with an impurity.

According to some embodiments, the cell region CR may constitute a memory cell region of a volatile memory device or a memory cell region of a non-volatile memory device. The memory cell region may be a memory cell region of a dynamic random access memory (DRAM), a memory cell region of a magnetic RAM (MRAM), a memory cell region of a static RAM (SRAM), a memory cell region of a phase change RAM (PRAM), a memory cell region of a resistance RAM (RRAM), or a memory cell region of a ferroelectric RAM (FRAM). The cell region CR may include a DRAM memory cell, an MRAM memory cell, an SRAM memory cell, a PRAM memory cell, a RRAM memory cell, and/or an FRAM memory cell. The cell region CR may include a unit memory cell having a transistor and a capacitor or a unit memory cell having a switching device and a variable resistor.

Peripheral circuits needed to drive (operate) memory cells in the cell region CR may be (arranged) in the peripheral circuit region PR.

In the interface region IF, a plurality of conductive lines for (electrical) connection between the cell region CR and the peripheral circuit region PR and insulation structures for insulation between the cell region CR and the peripheral circuit region PR may be positioned (arranged).

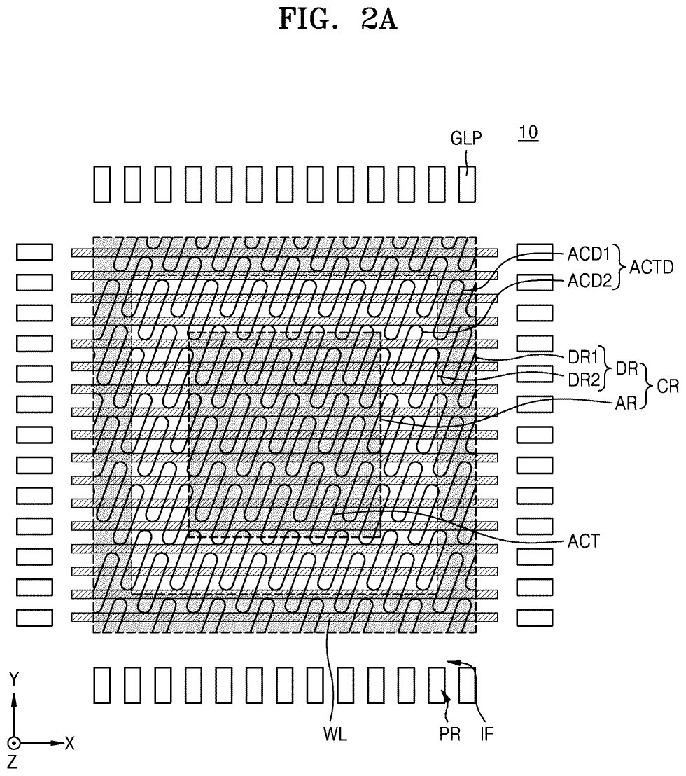

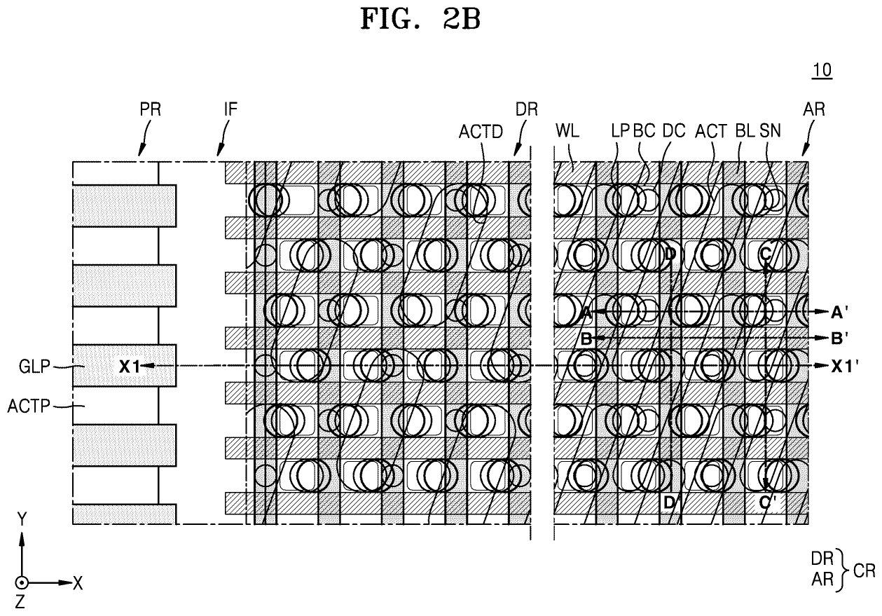

FIG. 2A is a plan view illustrating a schematic configuration of the semiconductor device 10 according to embodiments.

FIG. 2B is a schematic plan view that enlarges a portion of FIG. 2A.

As shown in FIGS. 2A and 2B, the semiconductor device 10 may include the cell region CR, the peripheral circuit region PR, and the interface region IF between the cell region CR and the peripheral circuit region PR. According to some embodiments, the cell region CR may include an active cell region AR and a dummy cell region DR adjacent to (e.g., extending around or at least partially surrounding) the active cell region AR, a plurality of active patterns ACT may be (arranged) in (on) the active cell region AR, and a plurality of dummy active patterns ACTD may be (arranged) in (on) the dummy cell region DR.

In some embodiments, an active pattern ACT may have an elliptical shape having a long (longer) axis (also referred to as a major axis) and a short (shorter) axis (also referred to as a minor axis) in a plan view. A dummy active pattern ACTD may have an elliptical shape having a long (longer) axis (also referred to as a major axis) and a short (shorter) axis (also referred to as a minor axis) in a plan view. However, the shapes of the active pattern ACT and the dummy active pattern ACTD are not limited the embodiments described above. According to some embodiments, the plurality of active patterns ACT in the active cell region AR may be arranged to have long axes in a diagonal direction with respect to the first horizontal direction (e.g., X direction) and the second horizontal direction (e.g., Y direction). According to some embodiments, the plurality of dummy active patterns ACTD in the dummy cell region DR may be arranged to have long axes in a diagonal direction with respect to the first horizontal direction (e.g., X direction) and the second horizontal direction (e.g., Y direction). According to some embodiments, the horizontal area of the plurality of dummy active patterns ACTD may be relatively greater (larger) than the horizontal area of the plurality of active patterns ACT. In some embodiments, a single dummy active pattern ACTD may be greater than a single active pattern ACT in a plan view. The plurality of dummy active patterns ACTD (e.g., each of the plurality of dummy active patterns ACTD) may have an island-like shape having a long axis in a diagonal direction with respect to the first horizontal direction (e.g., X direction) and the second horizontal direction (e.g., Y direction) when viewed from above, similarly as the plurality of active patterns ACT (e.g., each of the plurality of active patterns ACT). However, it is merely an example, and the shape of the plurality of dummy active patterns ACTD is not limited thereto. For example, (each of) the plurality of dummy active patterns ACTD may have an island-like shape with a relatively longer major axis than that of (each of) the plurality of active patterns ACT.

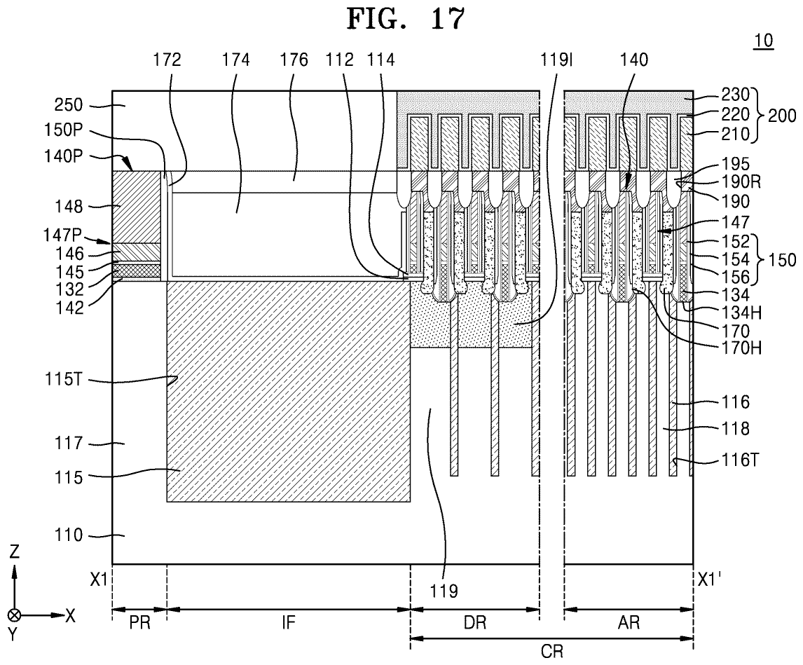

According to some embodiments, the plurality of active patterns ACTs may constitute a plurality of active patterns 118 shown in FIG. 17. The plurality of dummy active patterns ACTD may constitute a plurality of dummy active patterns 119 as shown in FIG. 17. For example, a single active pattern ACT may correspond to a single active pattern 118, and a single dummy active pattern ACTD may correspond to a single dummy active pattern 119.

According to some embodiments, the dummy cell region DR may include a first dummy cell region DR1 adjacent to the peripheral circuit region PR and a second dummy cell region DR2 adjacent to the active cell region AR. The second dummy cell region DR2 may be provided between the first dummy cell region DR1 and the active cell region AR. A dummy active pattern ACTD on the first dummy cell region DR1 may be referred to as a first dummy active pattern ACD1, and a dummy active pattern ACTD on the second dummy cell region DR2 may be referred to as a second dummy active pattern ACD2.

The plurality of dummy active patterns ACTD may include the first dummy active pattern ACD1 adjacent to the peripheral circuit region PR and the second dummy active pattern ACD2 adjacent to an active cell region AR. The first dummy active pattern ACD1 may face the peripheral circuit region PR, and the second dummy active pattern ACD2 may be spaced apart from the peripheral circuit region PR with the first dummy active pattern ACD1 therebetween.

According to some embodiments, (at least) some of the plurality of dummy active patterns ACTD may have upper surfaces lower than the vertical level of the upper surfaces of the active patterns ACT. For example, the first dummy active pattern ACD1 may have the upper surface lower than the vertical level of the upper surface of an active pattern ACT.

According to some embodiments, some of the plurality of dummy active patterns ACTD may have upper surfaces having a vertical level different from a vertical level of the upper surfaces of the remaining dummy active patterns ACTD. For example, the first dummy active pattern ACD1 may have the upper surface lower than the vertical level of the upper surface of the second dummy active pattern ACD2, and the second dummy active pattern ACD2 may have the upper surface higher than the vertical level of the upper surface of the first dummy active pattern ACD1. The vertical level of the upper surface of the dummy active pattern ACTD will be described in detail later in the description of a manufacturing process.

According to some embodiments, a plurality of word lines WL may extend parallel to each other in the first horizontal direction (e.g., X direction) across (overlapping) the plurality of active patterns ACT and the plurality of dummy active patterns ACTD on (in) the cell region CR. A plurality of bit lines BL may extend parallel to one another in the second horizontal direction (Y direction) crossing the first horizontal direction (X direction) over the plurality of word lines WL.

According to some embodiments, a plurality of buried contacts BC may be formed between two bit lines BL adjacent to each other from among the plurality of bit lines BL. According to some embodiments, the plurality of buried contacts BC may be linearly arranged in the first horizontal direction (e.g., X direction) and the second horizontal direction (e.g., Y direction).

A plurality of landing pads LP may be formed on the buried contacts BC. The plurality of landing pads LP may be arranged to at least partially overlap the plurality of buried contacts BC (in the vertical direction (e.g., Z direction)). According to some embodiments, the plurality of landing pads LP may each extend to the upper portion of any one of the two bit lines BL adjacent to each other.

A plurality of storage nodes SN may be formed on the plurality of landing pads LP. The plurality of storage nodes SN may be formed above the plurality of bit lines BL. The plurality of storage nodes SN may be lower electrodes of a plurality of capacitors, respectively. A storage node SN may be (electrically) connected to the active pattern ACT via a landing pad LP and a buried contact BC.

According to some embodiments, a plurality of gate line patterns GLP constituting a plurality of logic transistors may be (arranged) in (on) the peripheral circuit region PR. In the peripheral circuit region PR of the drawings, other components except the plurality of gate line patterns GLP may be omitted for convenience of illustration. The plurality of gate line patterns GLP may extend from a portion of the peripheral circuit region PR close (closer) to the cell region CR toward a portion of the peripheral circuit region PR far (farther) from the cell region CR, but the inventive concept is not limited thereto. Also, the shapes of the plurality of gate line patterns GLP shown in FIGS. 2A and 2B are merely example, and the plurality of gate line patterns GLPs may have various widths, may be curved, or have varying widths and extend in various horizontal directions (e.g., X direction and/or Y direction).

According to some embodiments, as shown in FIG. 2B, a plurality of peripheral circuit active patterns ACTP may be arranged in (on) the peripheral circuit region PR. In the peripheral circuit region PR of the drawings, other components except for the plurality of peripheral circuit active patterns ACTP and the plurality of gate line patterns GLP may be omitted for convenience of illustration.

The plurality of gate line patterns GLP may be formed at the same vertical level as the plurality of bit lines BL. According to some embodiments, the plurality of gate line patterns GLP and the plurality of bit lines BL may include the same material or at least partially include the same material. For example, all or a part of a process for forming the plurality of gate line patterns GLP and all or a part of a process for forming the plurality of bit lines BL may be the same process.

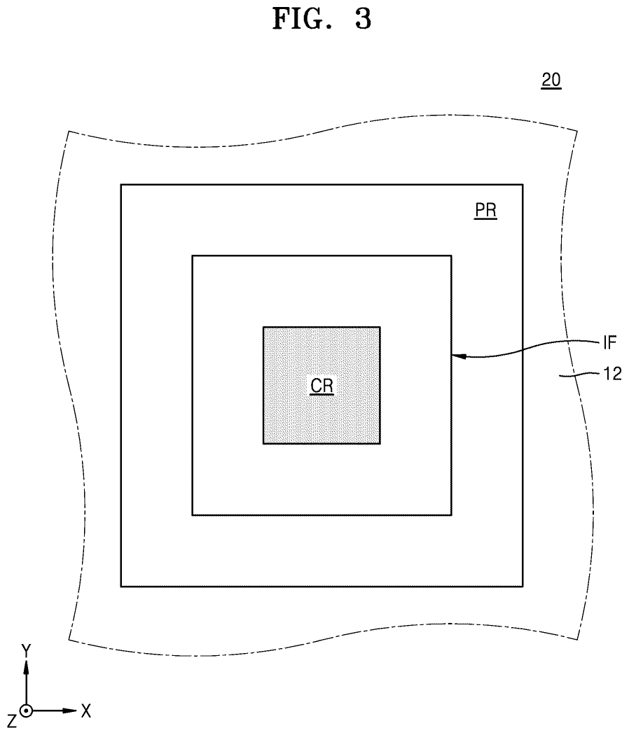

FIG. 3 is a plan view illustrating a schematic configuration of a semiconductor device 20 according to embodiments.

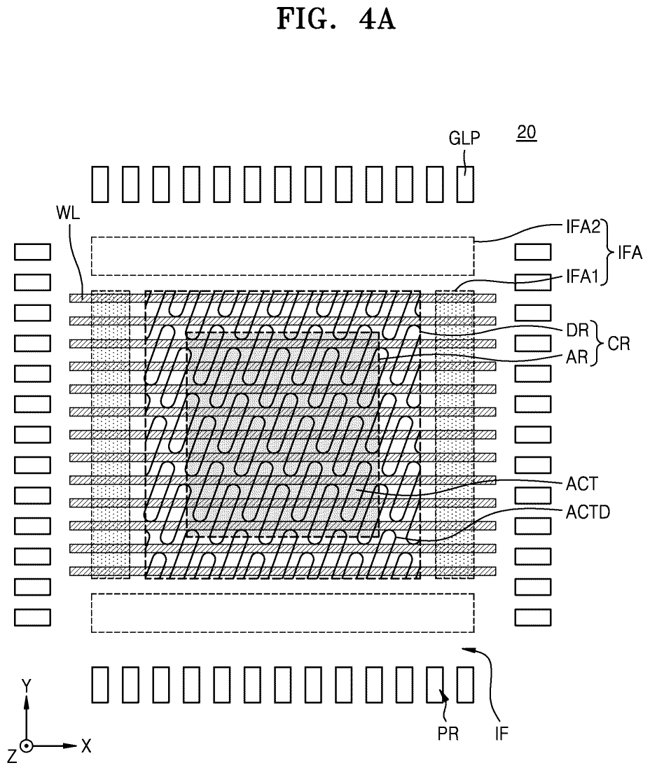

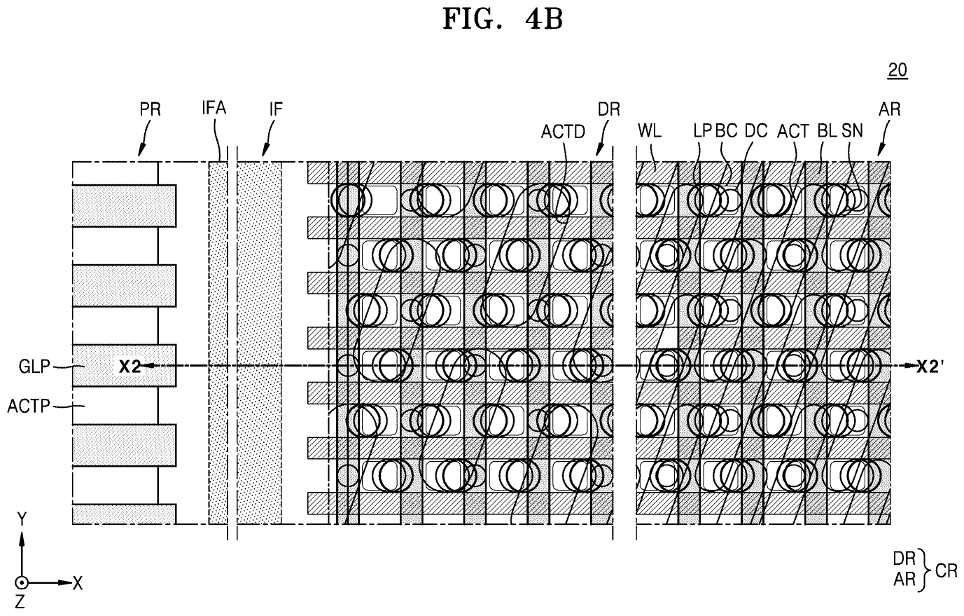

FIG. 4A is a plan view illustrating a schematic configuration of the semiconductor device 20 according to embodiments.

FIG. 4B is a schematic plan view that enlarges a portion of FIG. 4A.

Since the semiconductor device 20 may be configured similarly as the semiconductor device 10, detailed descriptions of the common configuration with the semiconductor device 10 may be omitted, and differences from the semiconductor device 10 will be described in detail.

The semiconductor device 20 may include the substrate 12 including the cell region CR, the peripheral circuit region PR extending around (e.g., at least partially surrounding in a plan view) the cell region CR, and the interface region IF provided between the cell region CR and the peripheral circuit region PR.

In a plan view, the size (area) of the cell region CR may be less than the size (area) of the interface region IF. In a plan view, the size (area) of the interface region IF may be less than the size (area) of the peripheral circuit region PR.

According to some embodiments, an interface active pattern IFA may be disposed in (on) an interface region IF. The interface active pattern IFA may act as a dam structure. The shape of the interface active pattern IFA is not limited to that shown in the drawings and may include one or more shapes, have various widths, have curves, or have varying widths and extend in various horizontal directions (e.g., X direction and/or Y direction).

According to some embodiments, the interface active pattern IFA may include a first interface active pattern IFA1 facing the cell region CR in a direction in which the word lines WL extend and a second interface active pattern IFA2 facing the cell region CR in a direction intersecting the direction in which the plurality of word lines WL extend. For example, the first interface active pattern IFA1 may face the cell region CR in the first horizontal direction (e.g., X direction), and the second interface active pattern IFA2 may face the cell region CR in the second horizontal direction (e.g., Y direction). According to some embodiments, the first interface active pattern IFA1 may overlap the plurality of word lines WL in the vertical direction (e.g., Z direction), and the second interface active pattern IFA2 may not overlap the plurality of word lines WL in the vertical direction (e.g., Z direction).

According to some embodiments, the vertical level of the upper surfaces of (at least) some of interface active patterns IFA may be lower than the vertical level of the upper surfaces of active patterns ACT. For example, the vertical level of the upper surface of the first interface active pattern IFA1 may be lower than the vertical level of the upper surface of the active pattern ACT.

According to some embodiments, some of the plurality of interface active patterns IFA may have upper surfaces having a vertical level different from a vertical level of the upper surfaces of the remaining interface active patterns IFA. For example, the first interface active pattern IFA1 may have the upper surface lower than the vertical level of the upper surface of the second interface active pattern IFA2, and the second interface active pattern IFA2 may have the upper surface higher than the vertical level of the upper surface of the first interface active pattern IFA1. The vertical level of the upper surface of the interface active pattern IFA will be described in detail later in the description of a manufacturing process.

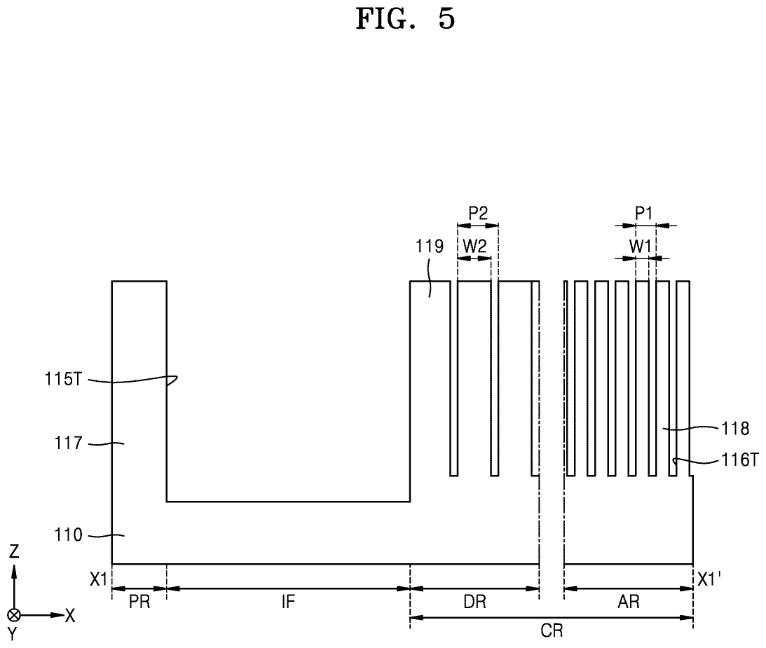

FIGS. 5 to 8 are drawings illustrating a method of manufacturing a semiconductor device according to embodiments.

In detail, FIGS. 5 to 8 are drawings for describing a method of manufacturing the semiconductor device 10 described above with reference to FIGS. 1, 2A, and 2B. In detail, FIGS. 5 to 8 are a cross-sectional views taken along a line X1-X1′ of FIG. 2B.

Referring to FIG. 5, a substrate 110 may be patterned by using a hard mask pattern (not shown) as an etching mask to form an interface trench 115T and a device isolation trench 116T, thereby forming a peripheral circuit active pattern 117, the plurality of active patterns 118, and the plurality of dummy active patterns 119. Although not shown in FIG. 5, a peripheral circuit trench (not shown) may be formed in (on) the peripheral circuit region PR, thereby forming a plurality of peripheral circuit active patterns adjacent to the peripheral circuit active pattern 117. In some embodiments, the substrate 110, the peripheral circuit active pattern 117, the plurality of active patterns 118, and the plurality of dummy active patterns 119 may correspond to the substrate 12, the peripheral circuit active pattern ACTP, the plurality of active patterns ACT, and the plurality of dummy active patterns ACTD in FIGS. 1, 2A, and 2B, respectively.

The substrate 110 may include, for example, a semiconductor element, such as Si and Ge, and/or a compound semiconductor, such as SiGe, SiC, GaAs, InAs, and InP. The substrate 110 may include a conductive region, e.g., a well doped with an impurity and/or a structure doped with an impurity.

The interface trench 115T in (on) the interface region IF may define a portion of the peripheral circuit active pattern 117 and a portion of a dummy active pattern 119, the device isolation trench 116T in (on) the active cell region AR may define an active pattern 118, and the device isolation trench 116T in (on) the dummy cell region DR may define the dummy active pattern 119. The device isolation trench 116T in (on) the active cell region AR may be referred to as a first trench in this specification, and the device isolation trench 116T in (on) the dummy cell region DR may be referred to as a second trench in this specification.

The plurality of active patterns 118 may (each) have a first width W1 and a first pitch P1 in the first horizontal direction (e.g., X direction). According to some embodiments, the first pitch P1 may have a value (about) twice as great (large) as the first width W1. The plurality of dummy active patterns 119 may (each) have a second width W2 and a second pitch P2 in the first horizontal direction (e.g., X direction). According to some embodiments, the second pitch P2 may have a value greater than the second width W2. According to some embodiments, the ratio of the second width W2 to the first width W1 may have a greater value than the ratio of the second pitch P2 to the first pitch P1. For example, the second width W2 may have a value (about) three times greater (larger) than the first width W1, and the second pitch P2 may have a value (about) twice greater (larger) than the first pitch P1.

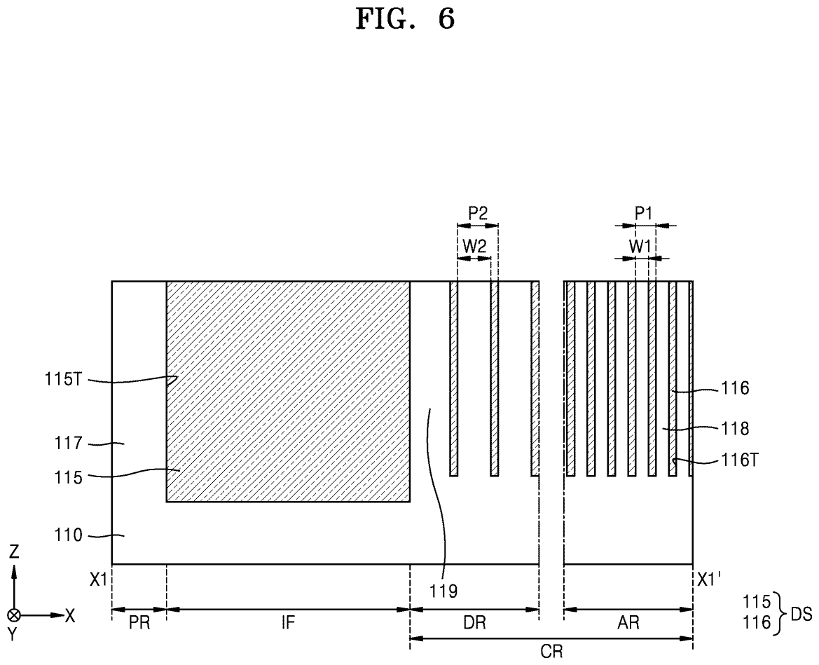

Referring to FIG. 6, an interface device isolation film 115 in (at least partially filling) the interface trench 115T and a device isolation film 116 in (at least partially filling) the device isolation trench 116T may be formed. The device isolation film 116 in (at least partially filling) the device isolation trench 116T, i.e., the first trench, in (on) the active cell region AR may be referred to as a first device isolation film, and the device isolation film 116 in (at least partially filling) the device isolation trench 116T, i.e., the second trench, in (on) the dummy cell region DR may be referred to as a second device isolation film. Although not shown in FIG. 6, a peripheral circuit device isolation film (not shown) may be formed to be in (e.g., to at least partially fill) the peripheral circuit trench (not shown) described in FIG. 5.

According to some embodiments, the interface trench 115T may be formed to have the lower surface (e.g., the bottom surface) vertically lower than the lower surface (e.g., the bottom surface) of the device isolation trench 116T, and the lower surface (e.g., the bottom surface) of the interface device isolation film 115 may be vertically lower than the lower surface (e.g., the bottom surface) of the device isolation film 116.

A portion of the peripheral circuit active pattern 117 and a portion of the dummy active pattern 119 may be defined on the substrate 110 by the interface device isolation film 115, and the plurality of active patterns 118 and the plurality of dummy active patterns 119 may be defined on the substrate 110 by the device isolation film 116. According to some embodiments, the interface device isolation film 115 and the device isolation film 116 may be formed together (e.g., formed by the same process or the same series of processes) and may be referred to together as a device isolation structure DS.

According to some embodiments, the device isolation structure DS may include a triple layer including a first insulation film, a second insulation film, and a third insulation film. For example, the first insulation film may be on (may conformally cover or overlap) the inner (side) surface(s) and the lower surface(s) (e.g., the bottom surfaces) of the interface trench 115T and the device isolation trench 116T. According to some embodiments, the first insulation film may include, for example, silicon oxide. For example, the second insulation film may be on (may conformally cover or overlap) the first insulation film. According to some embodiments, the second insulation film may include, for example, silicon nitride. For example, the third insulation film may be on (e.g., may cover or overlap) the second insulation film and fill (remaining portions of) the interface trench 115T and the device isolation trench 116T. According to some embodiments, the third insulation film may include silicon oxide. For example, the third insulation film may include silicon oxide formed of tonene silazene (TOSZ).

The device isolation structure DS is not limited to the structure described above. For example, the device isolation structure DS may include a single layer formed of one type of insulation film, a double layer formed of two types of insulation films, or a multilayer formed of a combination of at least four types of insulation films. For example, the device isolation film 116 and the interface device isolation film 115 may each include a single film made of silicon oxide.

According to some embodiments, the device isolation structure DS may further include a buried insulation pattern (not shown) at least partially buried on an upper portion (e.g., top) of the interface device isolation film 115. For example, the buried insulation pattern may include silicon nitride or polysilicon. The buried insulation pattern may be a structure to prevent unwanted residue from being deposited or remaining on the interface region IF. The buried insulation pattern may be formed in a loop-like shape that extends around (e.g., at least partially surrounds) the cell region CR on a plane (in a plan view).

Since the second width W2 and the second pitch P2 of the plurality of dummy active patterns 119 have values greater than the first width W1 and the first pitch P1 of the plurality of active patterns 118, respectively, the plurality of dummy active patterns 119 may perform the function of a dam that prevents warpage of the plurality of active patterns 118 when shrinkage occurs in a material forming the device isolation structure DS in the process of forming the device isolation structure DS including the interface device isolation film 115 and the device isolation film 116.

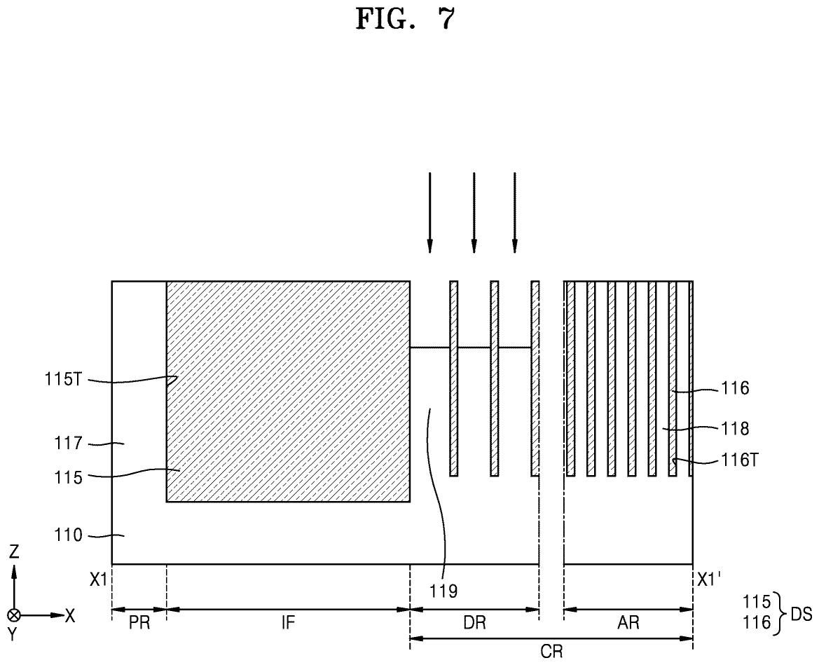

Referring to FIG. 7, to remove at least some of (at least a portion of) the plurality of dummy active patterns 119, a mask pattern (not shown) including a plurality of openings may be disposed on a result structure of FIG. 6, and an etching process may be performed on the plurality of dummy active patterns 119 exposed through the plurality of openings. The etching process may be performed as a wet etching process and/or a dry etching process.

According to some embodiments, some of (a portion of) the plurality of dummy active patterns 119 may remain after the etching process. According to some embodiments, through the etching process, the plurality of dummy active patterns 119 may be formed, such that the upper surfaces of the dummy active patterns 119 are formed at a lower vertical level than the upper surfaces of the plurality of active patterns 118. Also, through the etching process, the plurality of dummy active patterns 119 may be formed, such that the upper surfaces of the dummy active patterns 119 are formed at a lower vertical level than the upper surface of the peripheral circuit active pattern 117. According to some embodiments, after the etching process, the plurality of dummy active patterns 119 may be completely removed and the upper surface of the substrate 110 may be exposed.

According to some embodiments, at least a portion of a film material composed of silicon nitride or polysilicon on the interface device isolation film 115 may be removed together through the etching process. For example, at least a portion of the buried insulation pattern (not shown) including silicon nitride or polysilicon as described in FIG. 6 may be removed together. Therefore, a portion of the buried insulation pattern (not shown) protruding from the interface device isolation film 115 may be removed, and thus the interface device isolation film 115 may have a (relatively) flat upper surface.

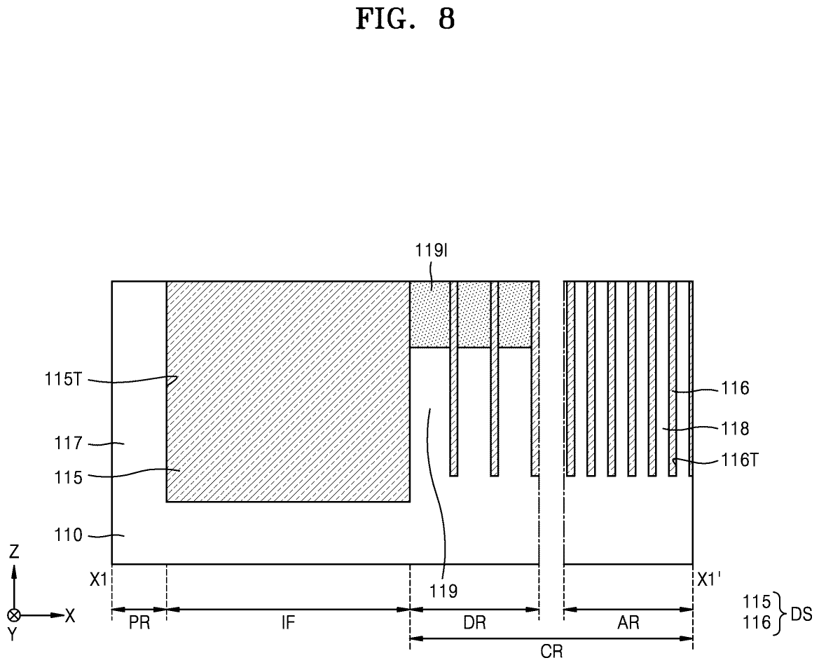

Referring to FIG. 8, an insulation pattern 119I may be formed inside a space formed by removing at least some (a portion) of the plurality of dummy active patterns 119 through the etching process of FIG. 7. The insulation pattern 119I may be formed through various deposition processes, e.g., a chemical vapor deposition (CVD).

According to some embodiments, the insulation pattern 119I may include a different material than the plurality of dummy active patterns 119, wherein the insulation pattern 119I may include various insulation materials, e.g., an oxide film, a nitride film, an ultra low-k (ULK) film having an ultra-low dielectric constant (k) from (about) 2.2 to (about) 2.4, and/or a combination thereof. In some embodiments, the insulation pattern 119I may include a tetraethyl orthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, and/or a combination thereof, but is not limited thereto.

As a comparative example, when at least some of the plurality of dummy active patterns 119 are not removed and an etching process is performed on the plurality of dummy active patterns 119 to deposit subsequent films, e.g., a conductive film such as the word lines WL, on the plurality of dummy active patterns 119, the etching process may not be performed to a depth sufficient to form the word lines WL due to the film quality of the plurality of dummy active patterns 119, and thus the subsequent film may not be continuously extended.

According to a manufacturing method according to embodiments, at least some (at least a portion) of the plurality of dummy active patterns 119 are (is) removed, an insulation pattern 119I is deposited inside a space formed by the removal of the at least some (at least a portion) of the plurality of dummy active patterns 119, and then a subsequent film is deposited, thereby reducing or preventing discontinuation of the subsequent film.

Also, before the at least some (at least a portion) of the plurality of dummy active patterns 119 are (is) removed, the stress applied to the substrate 110 due to shrinkage of the interface device isolation film 115 and the device isolation film 116 may be reduced by the plurality of dummy active patterns 119, and warpage of the plurality of active patterns 118 may be prevented. Ultimately, according to the manufacturing method according to embodiments, a semiconductor device with improved reliability may be provided.

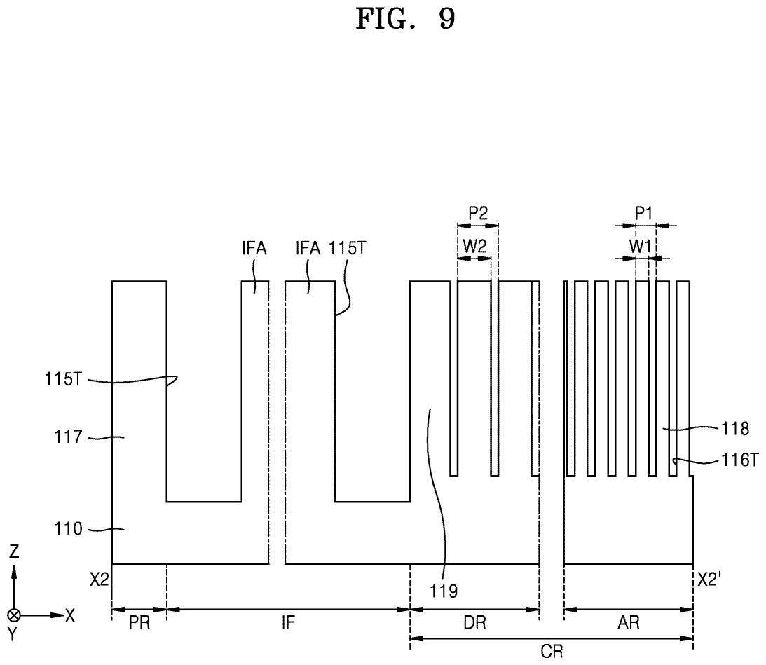

FIGS. 9 to 12 are drawings illustrating a method of manufacturing a semiconductor device according to embodiments.

In detail, FIGS. 9 to 12 are drawings for describing a method of manufacturing the semiconductor device 20 described above with reference to FIGS. 3, 4A, and 4B. Since the semiconductor device 20 is configured generally similarly as the semiconductor device 10 described with reference to FIGS. 1, 2A, and 2B, portions of the method of manufacturing the semiconductor device 20 common to the manufacturing process of the semiconductor device 10 described with reference to FIGS. 5 to 8 may be briefly described or omitted, and descriptions below will focus on differences therebetween.

Referring to FIG. 9, the substrate 110 may be patterned by using a hard mask pattern (not shown) as an etching mask to form the interface trench 115T and the device isolation trench 116T, thereby forming the peripheral circuit active pattern 117, the interface active pattern IFA, the plurality of active patterns 118, and the plurality of dummy active patterns 119. Although not shown in FIG. 9, a peripheral circuit trench (not shown) may be formed in (on) the peripheral circuit region PR, thereby forming a plurality of peripheral circuit active patterns adjacent to the peripheral circuit active pattern 117.

The interface trench 115T in (on) the interface region IF may define a portion of the peripheral circuit active pattern 117 and a portion of the interface active pattern IFA, another portion of the interface active pattern IFA and a portion of a dummy active pattern 119, the device isolation trench 116T in (on) the active cell region AR may define an active pattern 118, and the device isolation trench 116T in (on) the dummy cell region DR may define the dummy active pattern 119. The device isolation trench 116T in (on) the active cell region AR may be referred to as a first trench in this specification, and the device isolation trench 116T in (on) the dummy cell region DR may be referred to as a second trench in this specification. In some embodiments, the substrate 110, the peripheral circuit active pattern 117, the plurality of active patterns 118, the interface active pattern IFA, and the plurality of dummy active patterns 119 may correspond to the substrate 12, the peripheral circuit active pattern ACTP, the plurality of active patterns ACT, the interface active pattern IFA, and the plurality of dummy active patterns ACTD in FIGS. 3, 4A, and 4B, respectively.

The plurality of active patterns 118 may (each) have a first width W1 and a first pitch P1 in the first horizontal direction (e.g., X direction). According to some embodiments, the first pitch P1 may have a value (about) twice as great (large) as the first width W1. The plurality of dummy active patterns 119 may (each) have a second width W2 and a second pitch P2 in the first horizontal direction (e.g., X direction). According to some embodiments, the second pitch P2 may have a value greater than the second width W2. According to some embodiments, the ratio of the second width W2 to the first width W1 may have a greater value than the ratio of the second pitch P2 to the first pitch P1. For example, the second width W2 may have a value (about) three times greater (larger) than the first width W1, and the second pitch P2 may have a value (about) twice greater (larger) than the first pitch P1. According to some embodiments, the interface active pattern IFA may be formed to have a relatively greater horizontal width (in the first horizontal direction (e.g., X direction)) than each of the plurality of active patterns 118 and each of the plurality of dummy active patterns 119.

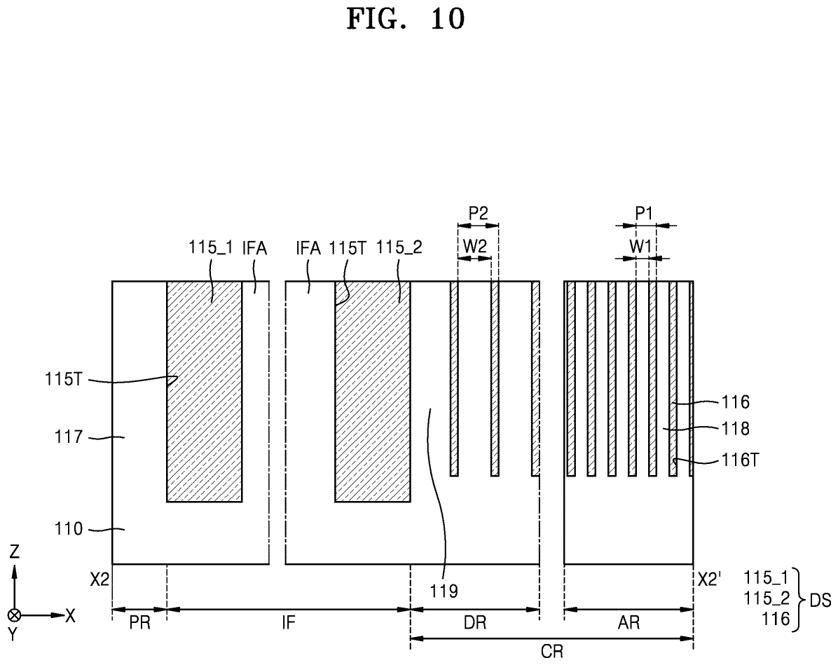

Referring to FIG. 10, interface device isolation films 115_1 and 115_2 (at least partially) filling the interface trench 115T and a device isolation film 116 (at least partially) filling the device isolation trench 116T may be formed. Although not shown in FIG. 10, a peripheral circuit device isolation film (not shown) may be formed to (at least partially) fill the peripheral circuit trench (not shown) described in FIG. 9.

A part of the peripheral circuit active pattern 117 and a part of the interface active pattern IFA may be defined on the substrate 110 by an interface device isolation film 115_1, another part of the interface active pattern IFA and a part of the dummy active pattern 119 may be defined on the substrate 110 by an interface device isolation film 115_2, and the plurality of active patterns 118 and the plurality of dummy active patterns 119 may be defined on the substrate 110 by the device isolation film 116. According to some embodiments, the interface device isolation films 115_1 and 115_2 and the device isolation film 116 may be formed together and may be referred to together as the device isolation structure DS. For example, the interface device isolation films 115_1 and 115_2 and the device isolation film 116 may be formed by the same process or the same series of processes.

According to some sembodiments, the device isolation structure DS may further include a buried insulation pattern (not shown) at least partially buried on an upper portion (e.g., top) of the interface device isolation film 115. The buried insulation pattern may be a structure to prevent unwanted residue from being deposited or remaining on the interface region IF. The buried insulation pattern may be formed in a loop-like shape that extends around (e.g., at least partially surrounds) the cell region CR on a plane (e.g., in a plan view).

Since the second width W2 and the second pitch P2 of (each of) the plurality of dummy active patterns 119 have values greater than the first width W1 and the first pitch P1 of (each of) the plurality of active patterns 118, the plurality of dummy active patterns 119 may reduce or prevent warpage of the plurality of active patterns 118 when shrinkage occurs in a material forming the device isolation structure DS in the process of forming the device isolation structure DS including the interface device isolation film 115 and the device isolation film 116. In other words, the plurality of dummy active patterns 119 may function as a dam structure.

Also, since the interface active pattern IFA is formed in (on) the interface region IF, the interface device isolation film 115 may be formed to have a relatively narrow horizontal width compared to when the interface active pattern IFA is not provided, may relatively reduce stress applied to the substrate 110 when shrinkage occurs in a material constituting the device isolation structure DS during the process of forming the device isolation structure DS, and reduce or prevent warpage of the plurality of active patterns 118. In other words, the interface active pattern IFA may act as a dam structure.

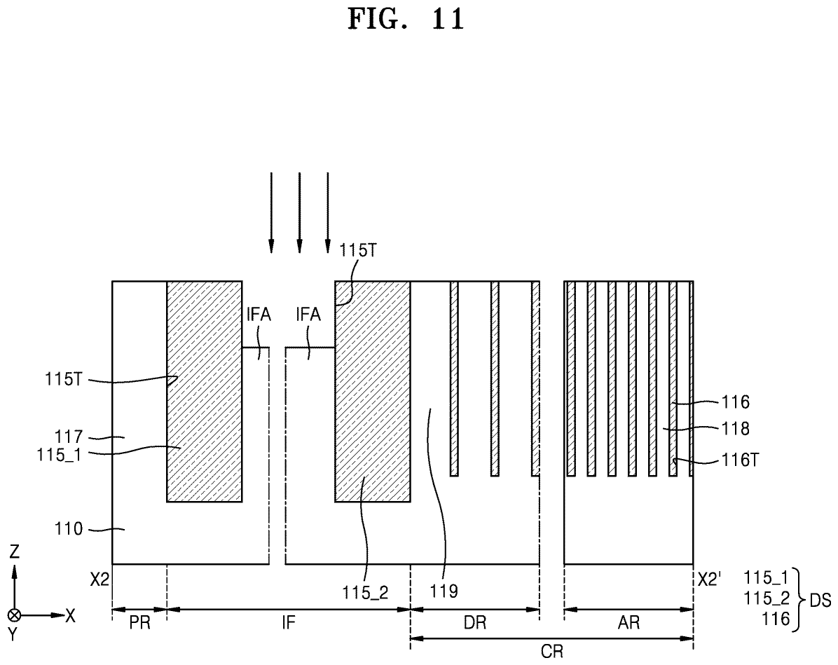

Referring to FIG. 11, to remove at least some of (at least a portion of) the plurality of interface active patterns IFA, a mask pattern (not shown) including a plurality of openings may be disposed on a result structure of FIG. 10, and an etching process may be performed on the plurality of interface active patterns IFA exposed through the plurality of openings. The etching process may be performed as a wet etching process and/or a dry etching process.

According to some embodiments, to remove at least some of (at least a portion of) the interface active patterns IFA and (at least a portion of) the plurality of dummy active patterns 119, a mask pattern (not shown) including a plurality of openings may be disposed on the result structure of FIG. 10, and an etching process may be performed on the interface active patterns IFA and the plurality of dummy active patterns 119 exposed through the plurality of openings.

According to some embodiments, some of the interface active patterns IFA may remain after the etching process. According to some embodiments, through the etching process, the interface active patterns IFA may be formed, such that the upper surfaces of the interface active patterns IFA are formed at a lower vertical level than the upper surfaces of the plurality of active patterns 118. Also, through the etching process, the plurality of interface active patterns IFA may be formed, such that the upper surfaces of the interface active patterns IFA are formed at a lower vertical level than the upper surface of the peripheral circuit active pattern 117. According to some embodiments, after the etching process, the interface active patterns IFA may be completely removed and the upper surface of the substrate 110 may be exposed.

According to some embodiments, at least a portion of a film material composed of silicon nitride and/or polysilicon on the interface device isolation film 115 may be removed together through the etching process. For example, at least a portion of the buried insulation pattern (not shown) including silicon nitride and/or polysilicon as described in FIG. 6 may be removed together. Therefore, a portion of the buried insulation pattern (not shown) protruding from the interface device isolation film 115 may be removed, and thus the interface device isolation film 115 may have a (relatively) flat upper surface.

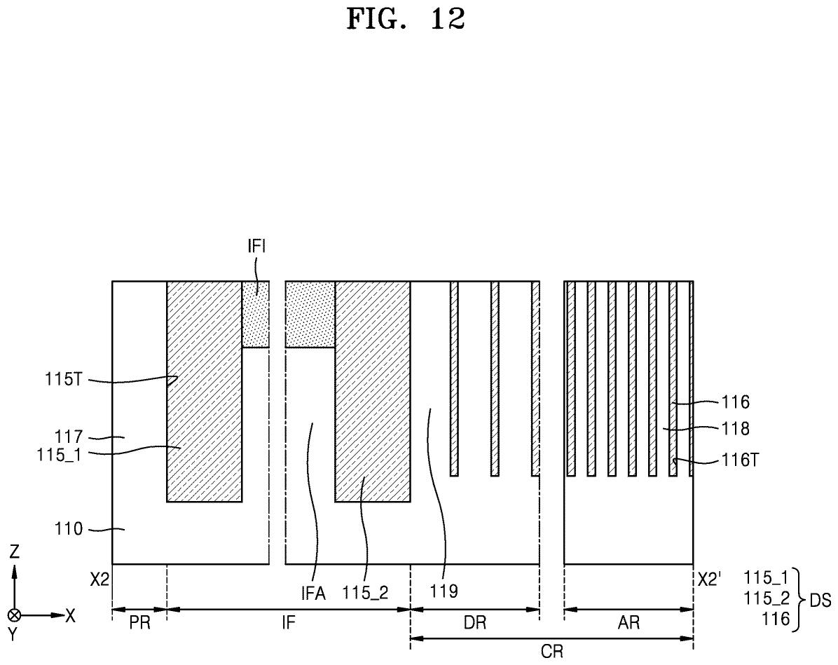

Referring to FIG. 12, an interface insulation pattern IFI may be formed within a space formed by removing at least some of (at least a portion of) the interface active patterns IFA through the etching process of FIG. 11. The interface insulation pattern IFI may be formed through various deposition processes, e.g., a chemical vapor deposition (CVD).

According to some embodiments, the interface insulation pattern IFI may include various insulation materials, e.g., an oxide film, a nitride film, an ultra low-k (ULK) film having an ultra low dielectric constant (k) from (about) 2.2 to (about) 2.4, and/or a combination thereof. In some embodiments, the interface insulation pattern IFI may include a tetraethyl orthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, and/or a combination thereof, but is not limited thereto.

As a comparative example, when at least some of the interface active patterns IFA are not removed and an etching process is performed on the interface active patterns IFA to deposit subsequent films, e.g., a conductive film such as the word lines WL, on the interface active patterns IFA, the etching process may not be performed to a depth sufficient to form the word lines WL due to the film quality of the interface active patterns IFA, and thus the subsequent film may not be continuously extended.

According to a manufacturing method according to embodiments, at least some of (at least a portion of) the interface active patterns IFA are (is) removed, an insulation pattern IFI is deposited inside a space formed by the removal of the at least some of (at least a portion of) the interface active patterns IFA, and then a subsequent film is deposited, thereby reducing or preventing discontinuation of the subsequent film.

Also, before the at least some of (at least a portion of) the interface active patterns IFA are (is) removed, the stress applied to the substrate 110 due to shrinkage of the interface device isolation film 115 may be reduced by the interface active patterns IFA, and warpage of the plurality of active patterns 118 may be reduced or prevented. According to the manufacturing method according to embodiments, a semiconductor device with improved reliability may be provided.

Hereinafeter, subsequent processes after the insulation pattern 119I and/or the interface insulation pattern IFI is/are formed are described.

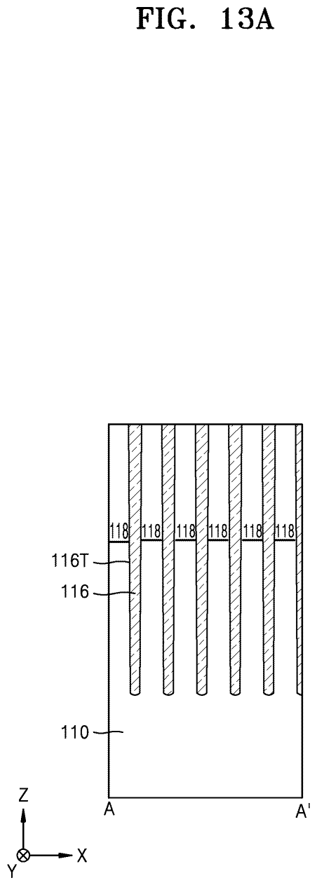

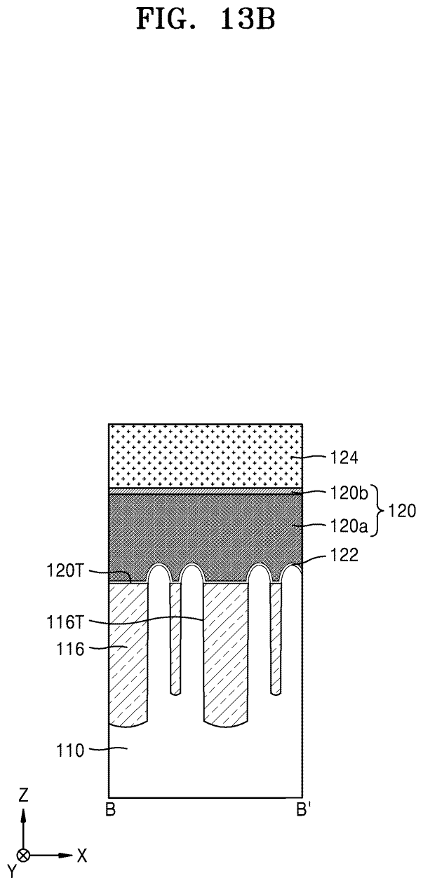

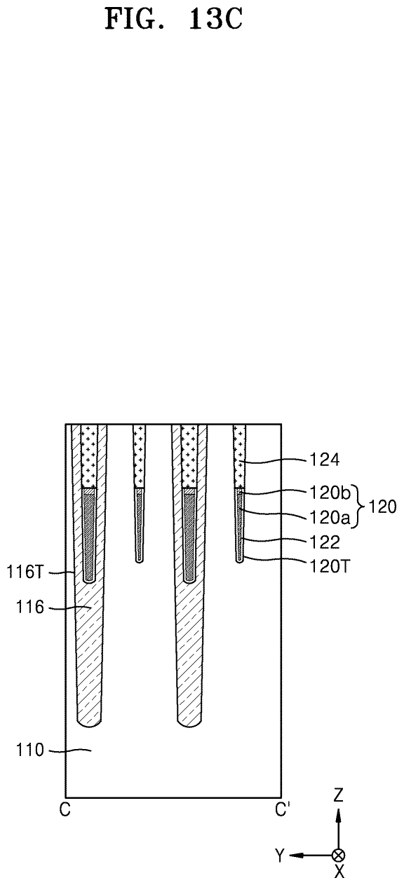

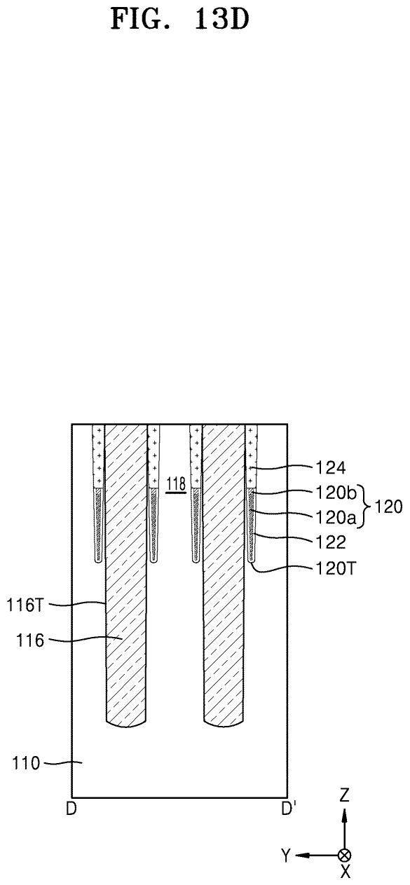

FIGS. 13A, 13B, 13C, 13D, 14A, 14B, 14C, 14D, 15A, 15B, 15C, 15D, 16A, 16B, 16C, and 16D are drawings illustrating a method of manufacturing a semiconductor device according to embodiments.

In detail, FIGS. 13A, 14A, 15A, and 16A are drawings respectively corresponding to cross-sections taken along a line A-A′ of FIG. 2B, FIGS. 13B, 14B, 15B, and 16B are drawings respectively corresponding to cross-sections taken along a line B-B′ of FIG. 2B, FIGS. 13C, 14C, 15C, and 16C are drawings respectively corresponding to cross-sections taken along a line C-C′ of FIG. 2B, and FIGS. 13D, 14D, 15D, and 16D are drawings respectively corresponding to cross-sections taken along a line D-D′ of FIG. 2B.

With reference to FIGS. 13A, 13B, 13C, 13D, 14A, 14B, 14C, 14D, 15A, 15B, 15C, 15D, 16A, 16B, 16C, and 16D, the manufacturing process for components on the active cell region AR is described, but the manufacturing process for components on the dummy cell region DR may also be performed similarly.

Referring to FIGS. 13A, 13B, 13C, and 13D together, a plurality of word line trenches 120T may be formed in the substrate 110 on which the plurality of active patterns 118 defined by the device isolation film 116 are formed. The plurality of word line trenches 120T may have a line shape that extends in the first horizontal direction (e.g., X direction) parallel to each other and are arranged at (generally) equal intervals in the second horizontal direction (e.g., Y direction) across the active pattern 118. According to some embodiments, steps may be formed on the lower surfaces (e.g., the bottom surfaces) of the plurality of word line trenches 120T. According to some embodiments, the plurality of word line trenches 120T may be formed by removing a portion of the substrate.

After cleaning a result structure in which the plurality of word line trenches 120T are formed, a plurality of gate dielectric films 122, a plurality of word lines 120, and a plurality of buried insulation films 124 may be sequentially formed inside the plurality of word line trenches 120T, respectively. The plurality of word lines 120 may have a line shape that extends in the first horizontal direction (e.g., X direction) parallel to each other and are arranged at (generally) equal intervals in the second horizontal direction (e.g., Y direction) across the active pattern 118. The plurality of word lines 120 may constitute the plurality of word lines WL shown in FIG. 2B. The upper surfaces of the plurality of word lines 120 may be positioned at a level lower than that of the upper surface of the substrate 110, i.e., the upper surfaces of the plurality of active patterns 118. The lower surfaces (e.g., the bottom surfaces) of the plurality of word lines 120 may have a concavo-convex shape, and a saddle fin transistor (saddle FinFET) may be formed on the plurality of active patterns 118.

The plurality of word lines 120 may (at least partially) fill lower portions of the plurality of word line trenches 120T. The plurality of word lines 120 may have a stacked structure of a lower word line layer 120a and an upper word line layer 120b. For example, the lower word line layer 120a may conformally cover (or overlap) the inner wall and the lower surface (e.g., the bottom surface) of a lower portion of the word line trench 120T with a gate dielectric film 122 therebetween. For example, the upper word line layer 120b may be on (may cover or overlap) the lower word line layer 120a and partially fill a lower portion of the word line trench 120T. According to some embodiments, the lower word line layer 120a may include a metal material, such as Ti, TiN, Ta, or TaN, and/or a conductive metal nitride. According to some embodiments, the upper word line layer 120b may include, for example, doped polysilicon, a metal material, such as W, a conductive metal nitride, such as WN, TiSiN, WSiN, and/or a combination thereof.

According to some embodiments, before or after forming the plurality of word lines 120, impurity ions may be implanted into portions of the active patterns 118 of the substrate 110 on both sides (e.g., opposite sides) of the plurality of word lines 120 to form source regions and drain regions within the plurality of active patterns 118.

The gate dielectric film 122 may cover (or overlap) the inner wall and the lower surface (e.g., the bottom surface) of the word line trench 120T. According to some embodiments, the gate dielectric film 122 may extend from between the word line 120 and the word line trench 120T to between a buried insulation film 124 and the word line trench 120T. The gate dielectric film 122 may include, for example, a silicon oxide, a silicon nitride, a silicon oxynitride, an oxide/nitride/oxide (ONO), and/or a high-k dielectric material having a dielectric constant higher than that of the silicon oxide. For example, the gate dielectric film 122 may have a dielectric constant from (about) 10 to (about) 25. According to some embodiments, the gate dielectric film 122 may include, for example, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and/or lead scandium tantalum oxide (PbScTaO). For example, the gate dielectric film 122 may include HfO2, Al2O3, HfAlO3, Ta2O3, and/or TiO2.

The plurality of buried insulation films 124 may (at least partially) fill upper portions of the plurality of word line trenches 120T. The upper surfaces of the plurality of buried insulation films 124 may be positioned at (substantially) the same level as the upper surface of the substrate 110. The buried insulation film 124 may include, for example, silicon oxide, silicon nitride, silicon oxynitride, and/or a combination thereof. For example, the buried insulation film 124 may include silicon nitride.

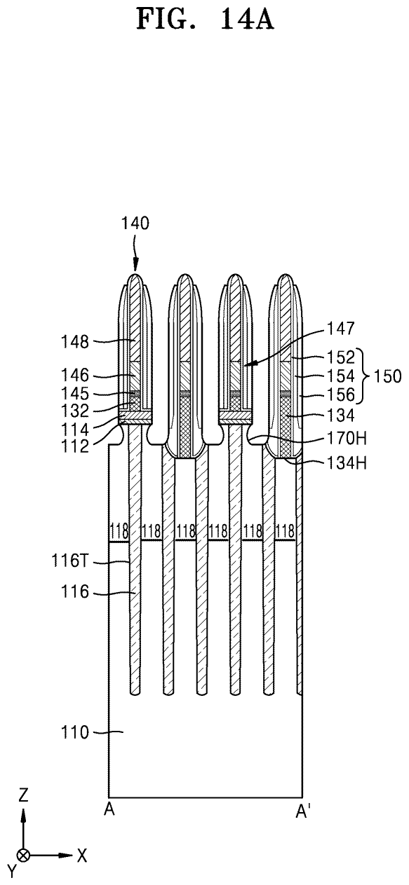

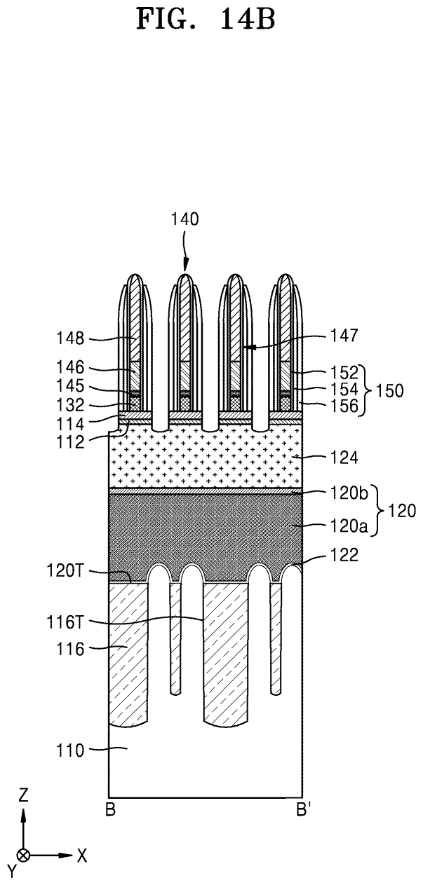

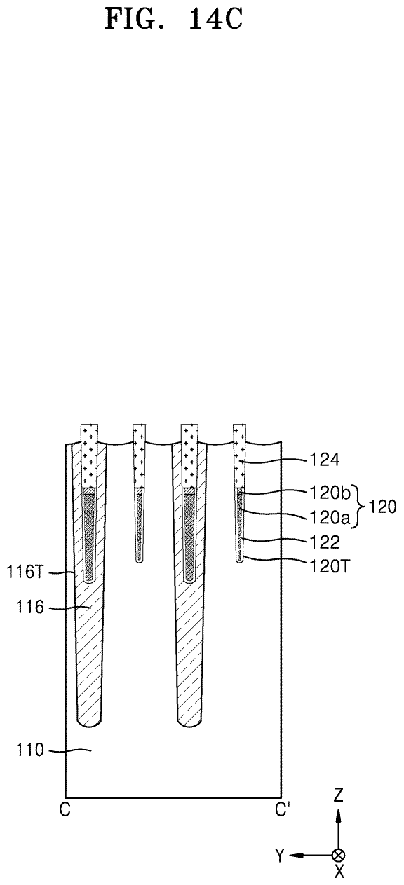

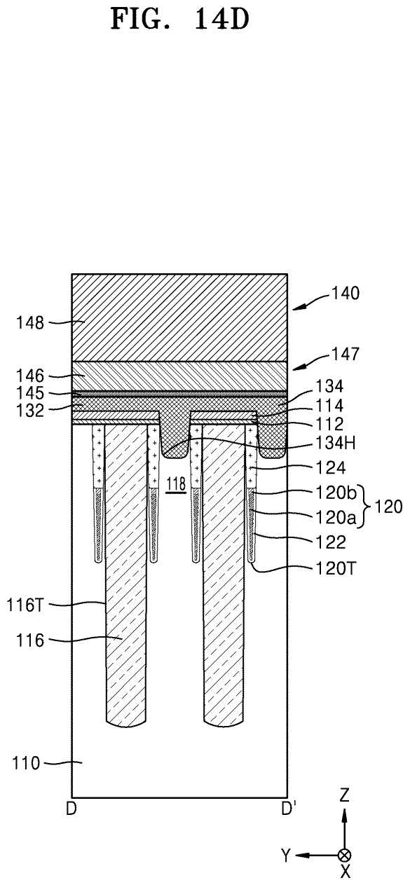

Referring to FIGS. 14A, 14B, 14C, and 14D together, insulation film patterns 112 and 114 on (covering or overlapping) the device isolation film 116, the plurality of active patterns 118, and the plurality of buried insulation films 124 may be formed. For example, the insulation film patterns 112 and 114 may include silicon oxide, silicon nitride, silicon oxynitride, a metal-based dielectric material, and/or a combination thereof. According to some embodiments, the insulation film patterns 112 and 114 may include a stacked structure of a plurality of insulation films including a first insulation film pattern 112 and a second insulation film pattern 114. According to some embodiments, the first insulation film pattern 112 may include, for example, silicon oxide, and the second insulation film pattern 114 may include, for example, silicon oxynitride. According to some embodiments, the first insulation film pattern 112 may include a non-metallic dielectric material, and the second insulation film pattern 114 may include a metallic dielectric material. According to some embodiments, the second insulation film pattern 114 may be formed thicker (in the vertical direction (e.g., Z direction)) than the first insulation film pattern 112. For example, the first insulation film pattern 112 may be formed to have a thickness from (about) 50 Å to (about) 90 Å (in the vertical direction (e.g., Z direction)), and the second insulation film pattern 114 may be formed to have a thickness thicker (in the vertical direction (e.g., Z direction)) than the first insulation film pattern 112 and from (about) 60 Å to (about) 100 Å.

Thereafter, after a conductive semiconductor layer is formed on the insulation film patterns 112 and 114, a direct contact hole 134H that extends into (e.g., penetrates through) the conductive semiconductor layer and the insulation film patterns 112 and 114 to expose a source region within the active pattern 118 may be formed, and then a direct contact conductive layer (at least partially) filling the direct contact hole 134H may be formed. According to some embodiments, the direct contact hole 134H may extend into the active pattern 118, i.e., into the source region. The conductive semiconductor layer may include, for example, doped polysilicon. The direct contact conductive layer may include, for example, doped polysilicon. According to some embodiments, the direct contact conductive layer may include an epitaxial silicon layer.

On the conductive semiconductor layer and the direct contact conductive layer, a metal-based conductive layer for forming a bit line structure 140 and an insulation capping layer are sequentially formed. According to some embodiments, the metal-based conductive layer may have a stacked structure of a first metal-based conductive layer and a second metal-based conductive layer. By etching the first metal-based conductive layer, the second metal-based conductive layer, and the insulation capping layer, a plurality of bit lines 147 each having a stacked structure of a first metal-based conductive pattern 145 and a second metal-based conductive pattern 146, and an insulation capping line 148 in a line shape may be formed.

According to some embodiments, the first metal-based conductive pattern 145 may include, for example, titanium nitride (TiN) or Ti—Si—N (TSN), and the second metal-based conductive pattern 146 may include, for example, tungsten (W) and/or tungsten silicide (WSix). According to some embodiments, the first metal-based conductive pattern 145 may function as a diffusion barrier. According to some embodiments, the plurality of insulation capping lines 148 may include silicon nitride.

One bit line 147 and one insulation capping line 148 on (covering or overlapping) the (corresponding) one bit line 147 may constitute one bit line structure 140. A plurality of bit line structures 140, each of which includes the bit line 147 and the insulation capping line 148 on (covering or overlapping) the bit line 147, may extend in the second horizontal direction (e.g., Y direction) parallel to the main surface of the substrate 110 and parallel to each other. The plurality of bit lines 147 may constitute the plurality of bit lines BL as shown in FIG. 2B. According to some embodiments, the bit line structure 140 may further include a conductive semiconductor pattern 132 that is a portion of the conductive semiconductor layer disposed between the insulation film patterns 112 and 114 and the first metal-based conductive pattern 145 (of the bit line 147).

In an etching process for forming the plurality of bit lines 147, a portion of the conductive semiconductor layer that does not vertically overlap with the bit lines 147 and a portion of the direct contact conductive layer may be removed together through the etching process to form a plurality of conductive semiconductor patterns 132 and a plurality of direct contact conductive patterns 134. At this time, the insulation film patterns 112 and 114 may perform the function of an etching stop film in an etching process for forming the plurality of bit lines 147, the plurality of conductive semiconductor patterns 132, and the plurality of direct contact conductive patterns 134. The plurality of direct contact conductive patterns 134 may form a plurality of direct contacts DC as shown in FIG. 2B. The plurality of bit lines 147 may be (electrically) connected to the plurality of active patterns 118 through the plurality of direct contact conductive patterns 134.

Both sidewalls (e.g., opposite sidewalls) of each of the plurality of bit line structures 140 may be (at least partially) covered (or overlapped) with an insulation spacer structure 150. A plurality of insulation spacer structures 150 may include a first insulation spacer 152, a second insulation spacer 154, and a third insulation spacer 156. The second insulation spacer 154 may include a material having a lower dielectric constant than (that of) the first insulation spacer 152 and (that of) the third insulation spacer 156. According to some embodiments, the first insulation spacer 152 and the third insulation spacer 156 may include nitride, and the second insulation spacer 154 may include oxide. According to some embodiments, the first insulation spacer 152 and the third insulation spacer 156 may include nitride, and the second insulation spacer 154 may include a material having an etching selectivity with respect to the first insulation spacer 152 and the third insulation spacer 156. For example, when the first insulation spacer 152 and the third insulation spacer 156 include nitride, the second insulation spacer 154 may include oxide, but the second insulation spacer 154 may be removed in a subsequent process to become an air spacer. According to some embodiments, the insulation spacer structure 150 may include the second insulation spacer 154 made of an oxide and the third insulation spacer 156 made of a nitride.

A plurality of insulation fences 180 may be formed in the space between a plurality of insulation spacer structures 150 on (covering or overlapping) both sidewalls (e.g., opposite sidewalls) of each of the plurality of bit line structures 140. The plurality of insulation fences 180 may be arranged in rows and spaced apart from each other between a pair of insulation spacer structures 150 (e.g., adjacent insulation spacer structures 150) facing each other from among a plurality of insulation spacer structures 150 on (covering or overlapping) both sidewalls (e.g., opposite sidewalls) of the plurality of bit line structures 140 (i.e., in the second horizontal direction (e.g., Y direction)). For example, the plurality of insulation fences 180 may include nitride.

According to some embodiments, the plurality of insulation fences 180 may be formed to extend into (e.g., extend through or penetrate) the insulation film patterns 112 and 114 and the buried insulation film 124, but the inventive concept is not limited thereto. According to some other embodiments, the plurality of insulation fences 180 may be formed to penetrate through the insulation film patterns 112 and 114 but not to extend into the buried insulation film 124, may be formed to extend into the insulation film patterns 112 and 114 but not to penetrate through the insulation film patterns 112 and 114, or may be formed, such that the lower surfaces (e.g., the bottom surfaces) of the plurality of insulation fences 180 contact the insulation film patterns 112 and 114 without extending into the insulation film patterns 112 and 114.

Between the plurality of bit lines 147, a plurality of buried contact holes 170H may be formed between the plurality of insulation fences 180. The plurality of buried contact holes 170H and the plurality of insulation fences 180 may be alternately arranged between adjacent (a pair of) insulation spacer structures 150 facing each other from among a plurality of insulation spacer structures 150 on (covering or overlapping) both sidewalls (e.g., opposite sidewalls) of the plurality of bit line structures 140 (i.e., in the second horizontal direction (e.g., Y direction)). The internal space of the plurality of buried contact holes 170H may be limited by the insulation spacer structure 150, the insulation fence 180, and the active pattern 118 on (covering or overlapping) sidewalls of each of two neighboring (adjacent) bit lines 147 from among the plurality of bit lines 147.

The plurality of buried contact holes 170H may be formed by removing portions of insulation film patterns 112 and 114 and the active pattern 118 by using the plurality of insulation capping lines 148, the insulation spacer structure 150 on (covering or overlapping) both sidewalls (e.g., opposite sidewalls) of the plurality of bit line structures 140, and the plurality of insulation fences 180 as etching masks. According to some embodiments, the plurality of buried contact holes 170H may be formed by first performing an anisotropic etching process to remove a portion of the insulation film patterns 112 and 114 and the active pattern 118 by using the plurality of insulation capping lines 148, the insulation spacer structure 150 on (covering or overlapping) both sidewalls (e.g., opposite sidewalls) of each of the plurality of bit line structures 140, and the plurality of insulation fences 180 as etching masks and then performing an isotropic etching process to further remove another portion of the active pattern 118, such that the space defined by the active pattern 118 (e.g., a lower portion of the buried contact hole 170H) is expanded.

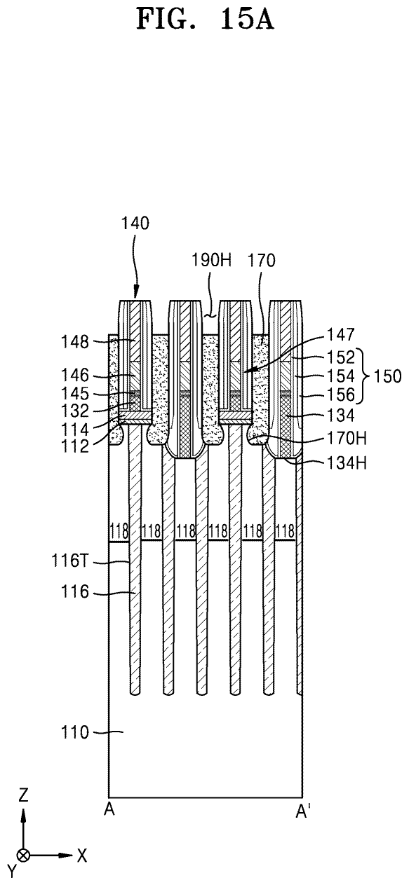

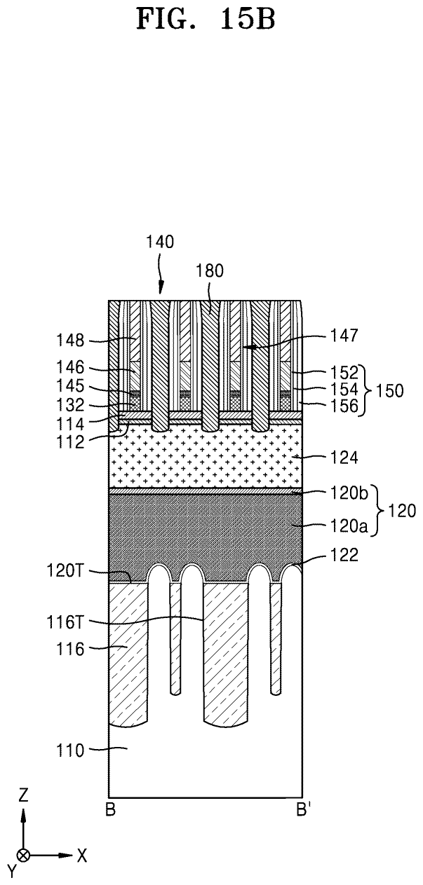

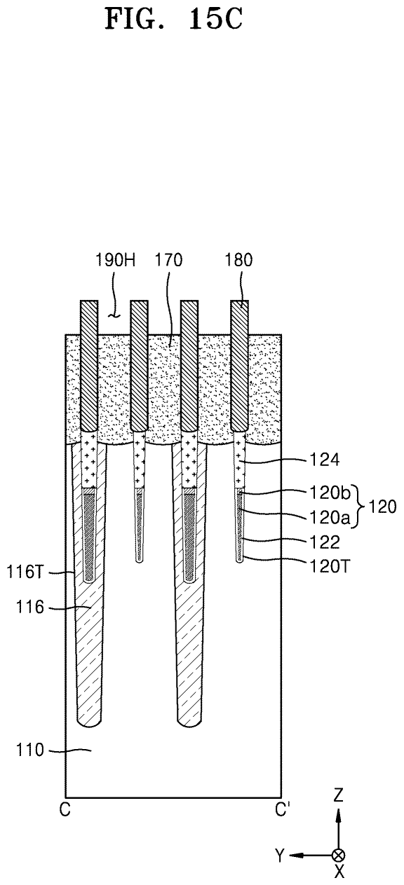

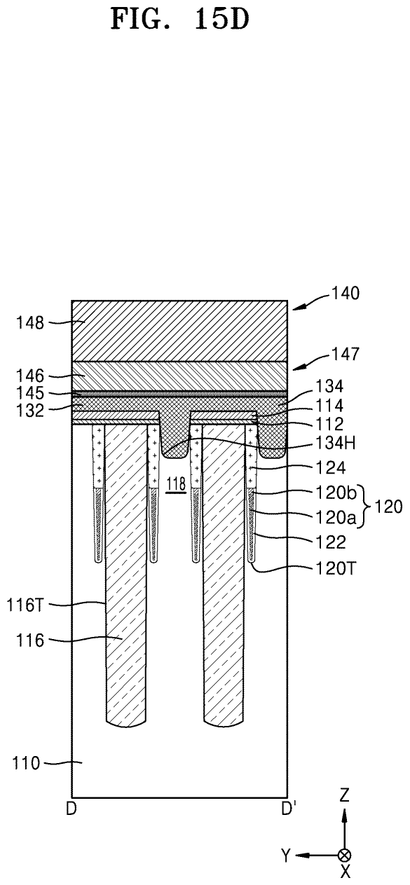

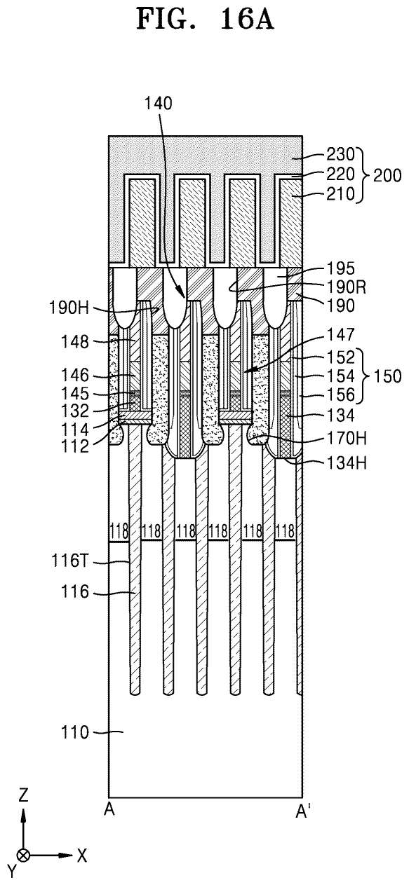

Referring to FIGS. 15A, 15B, 15C, and 15D together, a plurality of buried contacts 170 may be formed in the plurality of buried contact holes 170H. The plurality of buried contacts 170 and the plurality of insulation fences 180 may be alternately arranged between a pair of (adjacent) insulation spacer structures 150 facing each other from among a plurality of insulation spacer structures 150 on (covering or overlapping) both sidewalls (e.g., opposite sidewalls) of the plurality of bit line structures 140 (in the second horizontal direction (e.g., Y direction)). For example, the plurality of buried contacts 170 may include polysilicon.

According to some embodiments, the plurality of buried contacts 170 may be linearly arranged in the first horizontal direction (e.g., X direction) and the second horizontal direction (e.g., Y direction). The plurality of buried contacts 170 may each extend in the vertical direction (e.g., Z direction) perpendicular to the substrate 110 from (on) the active pattern 118. The plurality of buried contacts 170 may constitute the plurality of buried contacts BC as shown in FIG. 2B.

The plurality of buried contacts 170 may be arranged within the plurality of buried contact holes 170H, which are spaces defined by the plurality of insulation fences 180 and the plurality of insulation spacer structures 150 on (covering or overlapping) both sidewalls (e.g., opposite sidewalls) of a plurality of bit line structures 140. The plurality of buried contacts 170 may partially fill the lower portion of spaces between the plurality of insulation fences 180 and the plurality of insulation spacer structures 150 on (covering or overlapping) both sidewalls (e.g., opposite sidewalls) of a plurality of bit line structures 140.

The level of the upper surfaces of the plurality of buried contacts 170 may be positioned lower than the level of the upper surfaces of the plurality of insulation capping lines 148. The upper surfaces of the plurality of insulation fences 180 and the upper surfaces of the plurality of insulation capping lines 148 may be positioned at the same level with respect to the vertical direction (e.g., Z direction).

A plurality of landing pad holes 190H may be defined by the plurality of buried contacts 170, the plurality of insulation spacer structures 150, and the plurality of insulation fences 180. The plurality of buried contacts 170 may be exposed on the lower surfaces (e.g., the bottom surfaces) of the plurality of landing pad holes 190H.

In the process of forming the plurality of buried contacts 170, upper portion of the insulation capping line 148 and the insulation spacer structure 150 included in the bit line structure 140 may be removed, thereby lowering the level of the upper surface of the bit line structure 140.

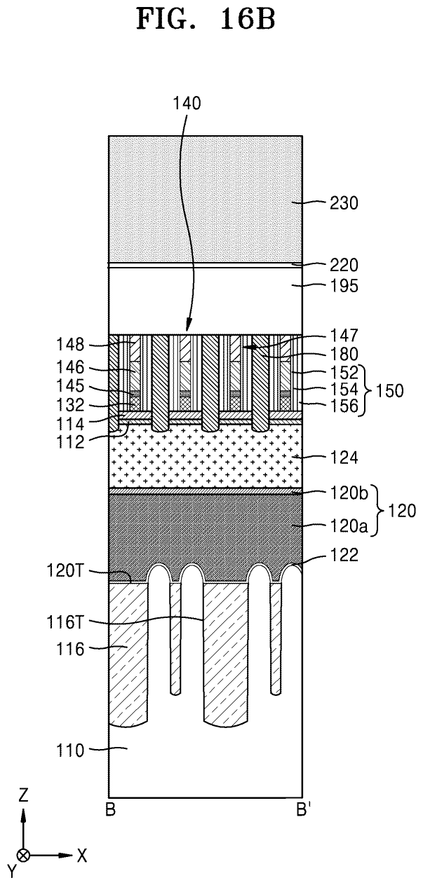

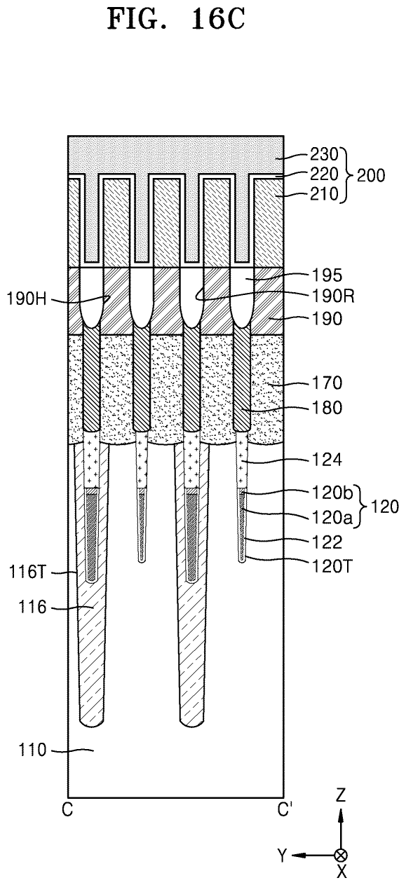

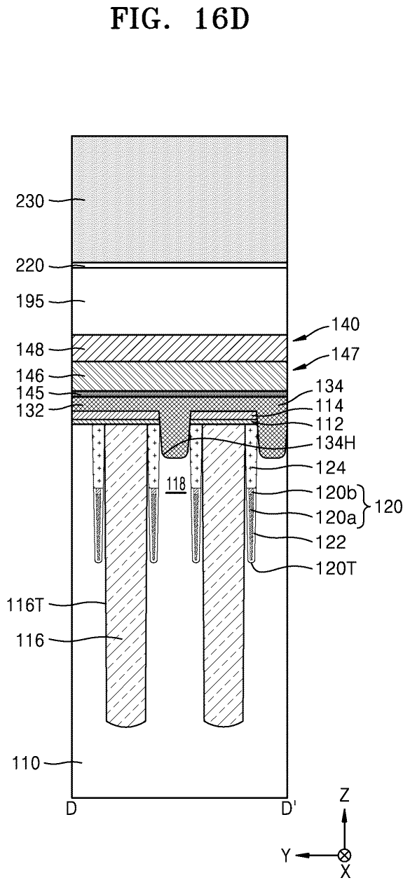

Referring to FIGS. 16A, 16B, 16C, and 16D together, thereafter, after (at least partially) filling the plurality of landing pad holes 190H and forming a landing pad material layer covering (or overlapping) the plurality of bit line structures 140, a portion of the landing pad material layer may be removed to form a recessed portion 190R. A plurality of landing pads 190 separated by the recessed portion 190R may be formed. The plurality of landing pads 190 may fill at least portions of the plurality of landing pad holes 190H and extend onto the plurality of bit line structures 140.

According to some embodiments, the landing pad material layer may include a conductive barrier film and a conductive pad material layer on the conductive barrier film. For example, the conductive barrier film may include a metal, a conductive metal nitride, and/or a combination thereof. According to some embodiments, the conductive barrier film may include a Ti/TiN stacked structure. According to some embodiments, the conductive pad material layer may include tungsten (W).

According to some embodiments, a metal silicide film may be formed on the plurality of buried contacts 170 prior to forming the landing pad material layer. The metal silicide film may be disposed between the plurality of buried contacts 170 and the landing pad material layer. The metal silicide film may include, but is not limited to, cobalt silicide (CoSix), nickel silicide (NiSix), or manganese silicide (MnSix).

The plurality of landing pads 190 may be spaced apart from each other with the recessed portion 190R therebetween. The plurality of landing pads 190 may be arranged on the plurality of buried contacts 170 and may extend onto the plurality of bit line structures 140. According to some embodiments, the plurality of landing pads 190 may extend over the plurality of bit lines 147. The plurality of landing pads 190 may be arranged on the plurality of buried contacts 170, such that the plurality of buried contacts 170 and the plurality of landing pads 190 corresponding to each other may be (electrically) connected to each other. The plurality of landing pads 190 may be (electrically) connected to the active pattern 118 via the plurality of buried contacts 170. The plurality of landing pads 190 may constitute the plurality of landing pads LP as shown in FIG. 2B. A buried contact 170 may be disposed between two bit line structures 140 adjacent to each other, and a landing pad 190 may extend from between the adjacent bit line structures 140 adjacent to each other with the buried contact 170 therebetween onto one bit line structure 140.

The recessed portion 190R may be (at least partially) filled with an insulation structure 195. According to some embodiments, the insulation structure 195 may include an interlayer insulation layer and an etch stop film. For example, the interlayer insulation layer may include oxide, and the etch stop film may include nitride.

Although the upper surface of the insulation structure 195 and the upper surfaces of the plurality of landing pads 190 are shown as being located at the same level, the inventive concept is not limited thereto. For example, the insulation structure 195 may have an upper surface that fills the recessed portion 190R and covers (or overlaps) the upper surfaces of the plurality of landing pads 190, thereby being positioned at a higher level than the upper surfaces of the plurality of landing pads 190. In FIGS. 15A and 15C, the upper surface of the insulation structure 195 and the bottom surface of a lower electrode 210 are shown as being located at the same level, but the inventive concept is not limited thereto.

A plurality of lower electrodes 210, a capacitor dielectric layer 220, and an upper electrode 230 may be sequentially formed on the plurality of landing pads 190. The plurality of lower electrodes 210, the capacitor dielectric layer 220, and the upper electrode 230 may form a plurality of capacitor structures 200. The plurality of lower electrodes 210 may be (electrically) connected to the plurality of landing pads 190, respectively. The capacitor dielectric layer 220 may conformally cover (or overlap) the surfaces of the plurality of lower electrodes 210.

According to some embodiments, the capacitor dielectric layer 220 may be formed integrally to cover (or overlap) the plurality of lower electrodes 210 together within a given region, e.g., within one active cell region (CR of FIG. 2B). According to some other embodiments, the capacitor dielectric layer 220 may be formed to cover (or overlap) both the active cell region AR and the peripheral circuit region (PR of FIG. 2B). The plurality of lower electrodes 210 may form the plurality of storage nodes SN as shown in FIG. 2B. According to some embodiments, the capacitor dielectric layer 220 may not be formed in a peripheral circuit region PR.

The plurality of lower electrodes 210 may each have a pillar-like shape, i.e., a column shape with the interior filled to have a circular horizontal cross-section, but is not limited thereto. According to some embodiments, the plurality of lower electrodes 210 may each have a cylindrical shape with a closed lower portion. According to some embodiments, the plurality of lower electrodes 210 may be arranged in a honeycomb-like shape in which the plurality of lower electrodes 210 are arranged in a zigzag manner with respect to the first horizontal direction (e.g., X direction) and/or the second horizontal direction (e.g., Y direction). According to some other embodiments, the plurality of lower electrodes 210 may be arranged in a matrix-like form in a row in each of the first horizontal direction (e.g., X direction) and the second horizontal direction (e.g., Y direction). The plurality of lower electrodes 210 may include, for example, a metal doped with impurities, such as silicon, tungsten, or copper, or a conductive metal compound, such as titanium nitride. Although not shown separately, at least one support pattern that contacts the sidewalls of the plurality of lower electrodes 210 may be further provided.

The capacitor dielectric layer 220 may include, for example, TaO, TaAlO, TaON, AlO, AlSiO, HfO, HfSiO, ZrO, ZrSiO, TiO, TiAlO, BST((Ba, Sr)TiO), STO(SrTiO), BTO(BaTiO), PZT(Pb(Zr, Ti)O), (Pb, La)(Zr, Ti)O, Ba(Zr, Ti)O, Sr(Zr, Ti)O, and/or a combination thereof.

The upper electrode 230 may include one of a doped semiconductor material layer, a main electrode layer, and an interface layer or a stacked structure of at least two of the above-stated layers. The doped semiconductor material layer may include, for example, doped polysilicon and/or doped polycrystalline silicon germanium (polySiGe). The main electrode layer may include a metal material. The main electrode layer may include, for example, W, Ru, RuO, Pt, PtO, Ir, IrO, SRO(SrRuO), BSRO((Ba, Sr)RuO), CRO(CaRuO), BaRuO, La(Sr, Co)O, etc. According to some embodiments, the main electrode layer may include W. The interfacial layer may include, for example, a metal oxide, a metal nitride, a metal carbide, and/or a metal silicide.

Hereinafter, the manufacturing process of components on the peripheral circuit region PR and the interface region IF and the final structure of a semiconductor device according to embodiments are described.

FIG. 17 is a cross-sectional view illustrating the semiconductor device 10 and a method of manufacturing the same according to embodiments.

In detail, FIG. 17 is a cross-sectional view taken along a line X1-X1′ of FIG. 2B.

Referring to FIG. 17, at least one gate line structure 140P may be formed on the peripheral circuit active pattern 117. The gate line structure 140P may include a gate line 147P arranged in the peripheral circuit region PR and an insulation capping line 148 on (covering or overlapping) one gate line 147P. The gate line 147P may include the first metal-based conductive pattern 145 and the second metal-based conductive pattern 146 arranged in the peripheral circuit region PR. A gate insulation film pattern 142 may be disposed between the gate line 147P and the peripheral circuit active pattern 117. According to some embodiments, the gate line structure 140P may further include the conductive semiconductor pattern 132 disposed between the gate insulation film pattern 142 and the first metal-based conductive pattern 145.

The conductive semiconductor pattern 132, the first metal-based conductive pattern 145, and the second metal-based conductive pattern 146 included in the gate line 147P may be formed together with the conductive semiconductor pattern 132, the first metal-based conductive pattern 145, and the second metal-based conductive pattern 146 included in the bit line structure 140 described above with reference to FIGS. 13A, 13B, 13C, and 13D.

According to some embodiments, the gate insulation film pattern 142 may have a stacked structure of at least two layers of a low-k dielectric material layer, an interfacial insulation layer, and a high-k dielectric material layer. For example, the gate insulation film pattern 142 may be a stacked structure of the low-k dielectric material layer and the high-k dielectric material layer or a stacked structure of the interfacial insulation layer and the high-k dielectric material layer. The low-k dielectric material layer may have a lower dielectric constant than the high-k dielectric material layer, but may be thicker than the high-k dielectric material layer. The interfacial dielectric layer may have a lower dielectric constant than the high-k dielectric material layer, but may be thicker than the high-k dielectric material layer.

For example, the low-k dielectric material layer may include silicon oxide. According to some embodiments, the low-k dielectric material layer may include plasma nitride oxide (PNO). According to some embodiments, the low-k dielectric material layer may have a thickness from (about) 60 Å to (about) 150 Å.

For example, the interfacial insulation layer may include silicon oxide. According to some embodiments, the interfacial insulation layer may include silicon oxide formed through thermal oxidation. According to some embodiments, the interfacial insulation layer may have a thickness from (about) 5 Å to (about) 20 Å.

For example, the high-k dielectric material layer may include silicon nitride, silicon oxynitride, and/or a high-k dielectric material having a higher dielectric constant than silicon oxide. According to some embodiments, the high-k dielectric material layer may include hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and/or lead scandium tantalum oxide (PbScTaO). According to some embodiments, the high-k dielectric material layer may have a thickness from (about) 10 Å to (about) 40 Å.

The sidewalls of the gate line structure 140P may be covered (or overlapped) by a gate insulation spacer 150P. The gate insulation spacer 150P may include, for example, a nitride film. According to some embodiments, the gate insulation spacer 150P may be formed as a single layer, but is not limited thereto, and may be formed as a multiple-layered structure of two or more layers. According to some embodiments, all or a part of the gate insulation spacer 150P and all or a part of the insulation spacer structure 150 may be formed together and include the same material.

Filling insulation layers 172, 174, and 176 may be formed around a plurality of gate line structures 140P. The filling insulation layers 172, 174, and 176 may be on (e.g., cover or overlap) the interface device isolation film 115. According to some embodiments, the filling insulation layers 172, 174, and 176 may have a stacked structure of a first filling insulation layer 172, a second filling insulation layer 174, and a third filling insulation layer 176. The first filling insulation layer 172 may conformally cover (or overlap) the interface device isolation film 115 and the insulation spacer structure 150. According to some embodiments, the first filling insulation layer 172 may include a nitride, the second filling insulation layer 174 may include an oxide, and the third filling insulation layer 176 may include a nitride. According to some embodiments, the upper surface of the second filling insulation layer 174 and the upper surface of the bit line structure 140 may be located at the same level. According to some embodiments, the upper surface of the third filling insulation layer 176 and the upper surface of the gate line structure 140P may be located at the same level.

The peripheral circuit region PR corresponding to the level where plurality of capacitor structures 200 are located may be (at least partially) filled with a buried insulation layer 250. For example, thee buried insulation layer 250 in the peripheral circuit region PR may overlap the plurality of capacitor structures 200 in a horizontal direction (e.g., X direction and/or Y direction). The buried insulation layer 250 may include, for example, an oxide film or an ultra-low K (ULK) film. The oxide film may be formed by a BoroPhosphoSilicate Glass (BPSG) film, a PhosphoSilicate Glass (PSG) film, a BoroSilicate Glass (BSG) film, an Un-doped Silicate Glass (USG) film, a Tetra Ethyle Ortho Silicate (TEOS) film, and/or a High Density Plasma (HDP) film. The ULK film may include a SiOC film and/or a SiCOH film having an ultra-low dielectric constant K from (about) 2.2 to (about) 2.4, for example.

In the active cell region AR, the active pattern 118, the word line 120, the gate dielectric film 122, the bit line 147, the buried contact 170, the landing pad 190, and a capacitor structure 200 may constitute a memory cell. In the dummy cell region DR, the dummy active pattern 119, the word line 120, the gate dielectric film 122, the bit line 147, the buried contact 170, the landing pad 190, and the capacitor structure 200 may constitute a dummy memory cell.

According to embodiments, the upper surfaces of the plurality of dummy active patterns 119 in the dummy cell region DR may be lower than the vertical level of the upper surfaces of the active patterns 118 (in the active cell region AR) and may be lower than the vertical level of the upper surface of the peripheral circuit active pattern 117 (in the peripheral circuit region PR).

According to embodiments, the insulation pattern 119I may be disposed on the plurality of dummy active patterns 119. The plurality of dummy active patterns 119 may be in contact with the lower portion of the sidewalls of the device isolation film 116, and the insulation pattern 119I may be in contact with the upper portion of the sidewalls of the device isolation film 116. The insulation pattern 119I may be provided between each of the plurality of dummy active patterns 119 and each of the plurality of direct contact conductive patterns 134, between each of the plurality of dummy active patterns 119 and the insulation spacer structure 150, between each of the plurality of dummy active patterns 119 and the insulation film patterns 112 and 114, and between each of the plurality of dummy active patterns 119 and each of the plurality of buried contacts 170 (in the vertical direction (e.g., Z direction)).

According to embodiments, the insulation pattern 119I may include a different material than the plurality of dummy active patterns 119, wherein the insulation pattern 119I may include various insulation materials, e.g., an oxide film, a nitride film, an ultra low-k (ULK) film having an ultra-low dielectric constant (k) from (about) 2.2 to (about) 2.4, and/or a combination thereof. For example, the insulation pattern 119I may include a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, and/or a combination thereof, but is not limited thereto.

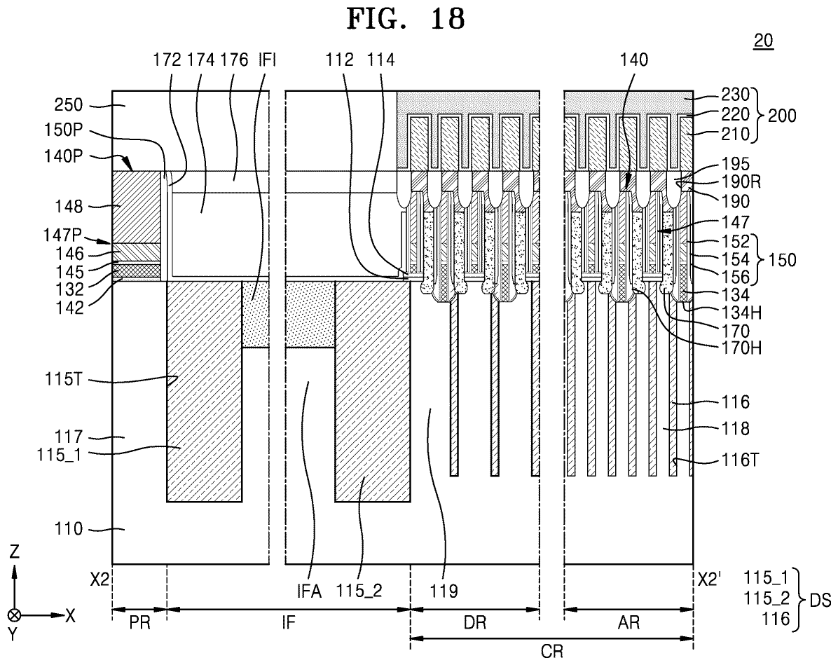

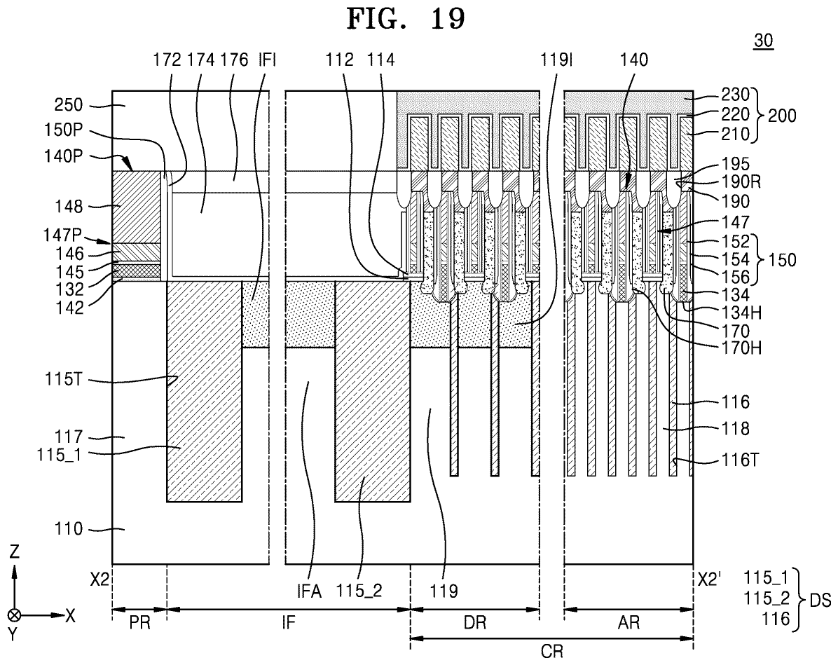

FIG. 18 is a cross-sectional view illustrating the semiconductor device 20 according to some embodiments. Since the semiconductor device 20 may be configured similarly as the semiconductor device 10 of FIG. 17, descriptions below mainly focus on differences between the semiconductor device 20 and the semiconductor device 10.

The semiconductor device 20 may include the peripheral circuit region PR, the cell region CR, and the interface region IF provided between the peripheral circuit region PR and the cell region CR. The cell region CR may include the active cell region AR and the dummy cell region DR. The semiconductor device 20 may include the peripheral circuit active pattern 117 on (in) the peripheral circuit region PR, the plurality of active patterns 118 on (in) the active cell region AR, the plurality of dummy active patterns 119 on (in) the dummy cell region DR, and the interface active pattern IFA on (in) the interface region IF.

In the active cell region AR, the active pattern 118, the word line 120, the gate dielectric film 122, the bit line 147, the buried contact 170, the landing pad 190, and a capacitor structure 200 may constitute a memory cell. In the dummy cell region DR, the dummy active pattern 119, the word line 120, the gate dielectric film 122, the bit line 147, the buried contact 170, the landing pad 190, and the capacitor structure 200 may constitute a dummy memory cell.

According to embodiments, the upper surface of the interface active pattern IFA in the interface region IF may be lower than the vertical level of the upper surfaces of the active patterns 118 and may be lower than the vertical level of the upper surface of the peripheral circuit active pattern 117.

According to embodiments, the interface insulation pattern IFI may be disposed on the interface active pattern IFA. The interface active pattern IFA may be in contact with lower portions of the sidewalls of interface device isolation film 115_1 and 115_2, and the interface insulation pattern IFI may be in contact with the upper portions of the sidewalls of the interface device isolation film 115_1 and 115_2. The interface insulation pattern IFI may be provided between the interface active pattern IFA and the filling insulation layers 172, 174, and 176 (in the vertical direction (e.g., Z direction)).

According to embodiments, the interface insulation pattern IFI may include a different material than the interface active pattern IFA, wherein the interface insulation pattern IFI may include various insulation materials, e.g., an oxide film, a nitride film, an ultra low-k (ULK) film having an ultra-low dielectric constant (k) from (about) 2.2 to (about) 2.4, and/or a combination thereof. For example, the interface insulation pattern IFI may include a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, and/or a combination thereof, but is not limited thereto.

FIG. 19 is a cross-sectional view illustrating a semiconductor device 30 according to some embodiments.

The semiconductor device 30 may be configured similarly as the semiconductor device 10 described with reference to FIG. 17 and the semiconductor device 20 described with reference to FIG. 18. In detail, the semiconductor device 30 may be an embodiment including the plurality of dummy active patterns 119 of the semiconductor device 10 and the interface active pattern IFA of the semiconductor device 20. Hereinafter, common parts with the semiconductor device 10 and the semiconductor device 20 are briefly described.

According to embodiments, the upper surface of the dummy active pattern 119 and the upper surface of the interface active pattern IFA may have lower vertical levels than the vertical levels of the upper surface of the peripheral circuit active pattern 117 and the upper surface of the active pattern 118. According to embodiments, the insulation pattern 119I may be disposed on the dummy active pattern 119, and the interface insulation pattern IFI may be disposed on the interface active pattern IFA, and the descriptions given above with reference to FIGS. 17 and 18 apply to the insulation pattern 119I and the interface insulation pattern IFI.

According to semiconductor devices 10, 20, and 30, the upper surface of the dummy active pattern 119 and the upper surface of the interface active pattern IFA may be formed at lower vertical levels than those of the upper surface of the peripheral circuit active pattern 117 and the upper surface of the active pattern 118. Therefore, subsequent films formed on the dummy active pattern 119 and the interface active pattern IFA during the manufacturing process may be deposited relatively easily, and a semiconductor device with relatively improved reliability may be provided.

Example embodiments have been disclosed in the drawings and specification as described above.

While the inventive concept has been particularly shown and described with reference to embodiments thereof, it will be understood that various changes in form and details may be made therein without departing from the scope of the following claims.

1. A semiconductor device comprising:
a substrate that comprises an active cell region, a dummy cell region that extends around the active cell region in a plan view, and a peripheral circuit region that extends around the dummy cell region in a plan view; and
a device isolation film in device isolation trenches in the active cell region and the dummy cell region,
wherein the substrate further comprises:
active patterns that are alternately arranged with the device isolation trenches in the active cell region; and
dummy active patterns that are alternately arranged with the device isolation trenches in the dummy cell region, and
at least one of the dummy active patterns has an upper surface that is closer than an upper surface of at least one of the active patterns to a lower surface of the substrate.

2. The semiconductor device of claim 1, wherein the dummy active patterns comprise:
a first dummy active pattern that faces the peripheral circuit region; and
a second dummy active pattern that is spaced apart from the peripheral circuit region with the first dummy active pattern therebetween, and
wherein an upper surface of the first dummy active pattern is closer than an upper surface of the second dummy active pattern to the lower surface of the substrate.

3. The semiconductor device of claim 1, further comprising a peripheral circuit active pattern in the peripheral circuit region,
wherein at least one of the dummy active patterns has an upper surface that is closer than an upper surface of the peripheral circuit active pattern to the lower surface of the substrate.

4. The semiconductor device of claim 3, wherein the dummy active patterns comprise:
a first dummy active pattern that faces the peripheral circuit region; and
a second dummy active pattern that is spaced apart from the peripheral circuit region with the first dummy active pattern therebetween,
wherein an upper surface of the first dummy active pattern is closer than the upper surface of the peripheral circuit active pattern to the lower surface of the substrate, and
wherein an upper surface of the second dummy active pattern is coplanar with the upper surface of the peripheral circuit active pattern or farther than the upper surface of the peripheral circuit active pattern from the lower surface of the substrate.

5. The semiconductor device of claim 3, further comprising an interface region between the dummy cell region and the peripheral circuit region,
wherein the interface region comprises an interface device isolation film between the peripheral circuit active pattern and the dummy active patterns, and
wherein a lower surface of the interface device isolation film is closer than a lower surface of the device isolation film to the lower surface of the substrate.

6. The semiconductor device of claim 1, wherein at least one of the dummy active patterns has a first width in a horizontal direction that is parallel with the lower surface of the substrate,
wherein at least one of the active patterns has a second width in the horizontal direction, and
wherein the first width is greater than the second width.

7. The semiconductor device of claim 1, further comprising an insulation pattern on the dummy active patterns,
wherein the dummy active patterns are in contact with a lower portion of a sidewall of the device isolation film, and
wherein the insulation pattern is in contact with an upper portion of the sidewall of the device isolation film.

8. The semiconductor device of claim 7, wherein the insulation pattern comprises a first material that is different from a second material in the dummy active patterns.

9. A semiconductor device comprising:
a substrate that comprises an active cell region, a peripheral circuit region, and an interface region between the active cell region and the peripheral circuit region;
an active pattern in the active cell region;
a peripheral circuit active pattern in the peripheral circuit region; and
an interface active pattern in the interface region,
wherein the interface active pattern is between the active pattern and the peripheral circuit active pattern, and
wherein an upper surface of the interface active pattern is closer than an upper surface of the active pattern to a lower surface of the substrate.

10. The semiconductor device of claim 9, further comprising a plurality of word lines that extend in a horizontal direction on the substrate,
wherein the interface active pattern comprises:
a first interface active pattern that overlaps the plurality of word lines in a vertical direction; and
a second interface active pattern that is free of an overlap with the plurality of word lines in the vertical direction, and
wherein an upper surface of the first interface active pattern is closer than the upper surface of the active pattern to the lower surface of the substrate,
wherein the horizontal direction is parallel with the lower surface of the substrate, and
wherein the vertical direction is perpendicular to the lower surface of the substrate.

11. The semiconductor device of claim 9, further comprising:
a word line that extends in a first horizontal direction on the substrate; and
a bit line that extends in a second horizontal direction that intersects the first horizontal direction, on the substrate,
wherein the interface active pattern comprises:
a first interface active pattern that faces the active cell region in the first horizontal direction; and
a second interface active pattern that faces the active cell region in the second horizontal direction,
wherein an upper surface of the first interface active pattern is closer than an upper surface of the second interface active pattern to the lower surface of the substrate.

12. The semiconductor device of claim 9, further comprising:
an interface device isolation film in the interface region; and
an interface insulation pattern on the interface active pattern,
wherein the interface active pattern is in contact with a lower portion of a sidewall of the interface device isolation film, and
wherein the interface insulation pattern is in contact with an upper portion of the sidewall of the interface device isolation film.

13. The semiconductor device of claim 12, wherein the interface insulation pattern comprises a first material that is different from a second material in the interface active pattern.

14. The semiconductor device of claim 9, further comprising:
a device isolation film that is adjacent the active pattern in the active cell region; and
an interface device isolation film that is adjacent the interface active pattern in the interface region,
wherein a lower surface of the interface device isolation film is closer than a lower surface of the device isolation film to the lower surface of the substrate.

15. The semiconductor device of claim 9, further comprising dummy active patterns in a dummy cell region that is between the active cell region and the interface region,
wherein an upper surface of the dummy active patterns is closer than the upper surface of the active pattern to the lower surface of the substrate.

16. The semiconductor device of claim 15, wherein the dummy active patterns comprise:
a first dummy active pattern facing the peripheral circuit region; and
a second dummy active pattern spaced apart from the peripheral circuit region with the first dummy active pattern therebetween, and
wherein an upper surface of the first dummy active pattern is closer than an upper surface of the second dummy active pattern to the lower surface of the substrate.

17-20. (canceled)

21. A semiconductor device comprising:
a substrate that comprises an active cell region, a peripheral circuit region, and an interface region between the active cell region and the peripheral circuit region;
an active pattern in the active cell region;
a peripheral circuit active pattern in the peripheral circuit region; and
an interface active pattern in the interface region,
wherein the interface active pattern is between the active pattern and the peripheral circuit active pattern,
wherein an upper surface of the active pattern is at a first distance from a lower surface of the substrate, and
wherein an upper surface of the interface active pattern is at a second distance from the lower surface of the substrate, and
wherein the second distance is different from the first distance.

22. The semiconductor device of claim 21, further comprising:
a dummy cell region between the active cell region and the interface region; and
a dummy active pattern in the dummy cell region,
wherein an upper surface of the dummy active pattern is at a third distance from the lower surface of the substrate, and
wherein the third distance is different from the first distance.

23. The semiconductor device of claim 22, wherein an upper surface of the peripheral circuit active pattern is at a fourth distance from the lower surface of the substrate, and
wherein the fourth distance is different from the second distance and the third distance.

24. The semiconductor device of claim 23, wherein the first distance is greater than the second distance and/or the third distance, and
wherein the fourth distance is greater than the second distance and/or the third distance.
